(19) United States
(12) Patent Application Publication
(10) Pub. No.: US 2026/0312404 A1
(43) Pub. Date: Oct. 8, 2026

(54) ENERGY STORAGE SYSTEMS AND METHODS FOR PREDICTIVE HEALTH MONITORING AND FAULT DETECTION FOR A POWER CONVERSION SYSTEM

(71) Applicant: LG Energy Solution, Ltd., Seoul (KR)

(72) Inventor: Dinesh Kumar Murugesan, Westborough, MA (US)

(73) Assignee: LG Energy Solution, Ltd., Seoul (KR)

(21) Appl. No.: 19/640,085

(22) Filed: Apr. 6, 2026

Related U.S. Application Data
(60) Provisional application No. 63/784,840, filed on Apr. 7, 2025.

(51) Int. Cl. H02J 3/0012; G01R 31/42; H02J 3/32; H02M 1/32; H05K 7/14; H05K 7/20; H02J 103/30

(52) U.S. Cl. CPC H02J 3/0012; G01R 31/42; H02J 3/32; H02M 1/327; H05K 7/1432; H05K 7/209; H02J 2103/30

(57) ABSTRACT

A method for predictive health monitoring of an inverter in a battery energy storage system includes receiving, by one or more processors, a data set associated with the inverter. One or more threshold values are determined based on a thermal health index or a humidity health index associated with the inverter. A machine learning model is applied to the data set to generate a determination that the data set meets the threshold values associated with a health assessment of the inverter. The machine learning model includes an inverter encoder layer configured to perform multi-head attention, pattern recognition, and cross-algorithm learning for processing the data set in real-time. One or more operations of the inverter are controlled based on the determination that the data set meets the threshold values associated with the health assessment of the inverter.

### CROSS-REFERENCE TO RELATED APPLICATIONS

This application claims benefit to U.S. Provisional Patent Application No. 63/784,840, filed Apr. 7, 2025, the contents of which are incorporated by reference in its entirety.

### TECHNICAL FIELD

Various embodiments of the present disclosure relate generally to systems and methods for battery energy storage system monitoring and control, and more particularly to machine learning-based predictive health assessment and fault detection for power conversion systems and transformers in battery energy storage systems.

### BACKGROUND

Battery Energy Storage Systems (BESS) have emerged as critical components in modern energy infrastructure. As renewable energy sources such as wind and solar power become increasingly integrated into electrical grids, their inherent intermittency creates challenges for grid stability and efficient power distribution. Beyond renewable energy applications, BESS also provides significant benefits for conventional energy generation systems by enabling load leveling, frequency regulation, and peak shaving for traditional power plants including coal, natural gas, and nuclear facilities. These systems help conventional generators operate more efficiently by reducing the need for rapid ramping, and by providing grid services that improve overall system reliability. BESS technology addresses these challenges by storing excess electricity generated during periods of low demand and releasing it during peak demand periods. This capability optimizes energy usage by reducing curtailment of renewable electricity, improving efficiency of (and reducing reliance on) fossil fuel-based power generation such as gas turbines, and supports climate change mitigation efforts by reducing greenhouse gas emissions. The importance of BESS technology continues to grow as the global energy transition accelerates and intermittent renewable sources capture larger shares of the electricity supply mix.

Commercially available batteries may include nickel-cadmium batteries, nickel-hydrogen batteries, nickel-zinc batteries, lithium, sodium-ion, lithium iron phosphate, lithium-sulfur, solid-state batteries, and the like. Among these, lithium batteries may be gaining attention due to their advantageous characteristics: they can be charged and discharged freely without memory effects, they exhibit very low self-discharge rates, and they provide high energy density compared to nickel-based alternatives. Similarly, sodium-ion batteries are emerging as promising alternatives to lithium batteries, driven by the abundance of sodium resources and their potential cost advantages..

In general, battery packs or racks typically comprise multiple cells or cell stacks arranged in series or parallel configurations. Each cell or cell stacks contains either a single battery cell or multiple battery cells connected in series. The operational state of each cell stack within the battery pack is continuously monitored by a controller equipped with a battery management system. Battery cells may be integrated directly into packs or racks, or alternatively organized into modules, with these modules then connected in series or parallel arrangements to form complete battery packs or racks. The state of each cell stack included in the battery pack may be monitored by a controller having a battery management system mounted thereon. The controller may output signals for controlling the balancing operation, cooling operation, and discharging operation based on the monitored state from each cell stack.

Conventional energy storage systems are typically configured in containerized units, where each container housing may include multiple battery racks, switchboards, HVAC systems, thermal runaway detection systems, fire suppression systems, ventilation equipment, power distribution units, monitoring sensors, safety interlocks, and other components. These containers are designed with sufficient capacity to accommodate all necessary energy storage system components within their structure. At grid scale, BESS units may be used to store reserve power to even power entire cities in the event of blackouts or other interruptions in electrical service.

The topology of a battery energy storage system may include a set of batteries connected to an inverter. The set of batteries may provide power to the inverter and be charged by the inverter, which may also be referred to as a power conversion system (PCS). The inverter may be connected to a transformer which is connected to the power grid. Information can be gathered from the set of batteries and the inverter based on a plurality of sensors.

Current BESS configurations may lack comprehensive health predicting capabilities for their components. Component failures are often detected too late, leading to system downtime and incurring substantial service and other associated costs. Maintenance is typically reactive rather than predictive, which may result in inefficient operations and unexpected failures. Current BESS configurations do not determine or predict the health or thermal behavior of any component within the BESS, including the set of batteries, inverter, or transformer.

Current PCS systems may lack comprehensive health predicting capabilities. Component failures are often detected too late, leading to system downtime and incurring substantial service and associated costs. Maintenance is typically reactive rather than predictive. For power transformers in BESS applications, current solutions may miss early-stage degradation patterns. With a medium voltage transformer's lead time of approximately 365 days on average, a failure may impact site operations substantially, and existing methods may need specialized equipment installation.

Many systems may lack early detection capabilities and may not provide comprehensive monitoring scope that covers power components such as power stacks with IGBTs or MOSFETs, capacitors, and filters.

The present disclosure is directed to overcoming one or more of these above-referenced challenges.

### SUMMARY OF THE DISCLOSURE

In some aspects, the techniques described herein relate to a method comprising: receiving, by one or more processors, a data set associated with an inverter of a battery energy storage system; determining one or more threshold values based on one or more of a thermal health index or a humidity health index associated with the inverter; applying, by the one or more processors, a machine learning model to the data set to generate a determination that the data set meets the one or more threshold values associated with a health assessment of the inverter, wherein the machine learning model includes an inverter encoder layer configured to perform multi-head attention, pattern recognition, and cross-algorithm learning for processing the data set in real-time; and controlling, by the one or more processors, one or more operations of the inverter based on the determination that the data set meets the one or more threshold values associated with the health assessment of the inverter.

In some aspects, the techniques described herein relate to a method wherein the machine learning model is trained by: receiving first data regarding one or more element attributes, wherein the first data is associated with the inverter; extracting one or more first features from the first data; extracting one or more second features from second data; and training the machine learning model to determine a correlation between the one or more element attributes and the health assessment, based on the one or more first features, and the one or more second features.

In some aspects, the techniques described herein relate to a method wherein the one or more first features includes one or more of a DC overcurrent, an open phase fault, a gate driver fault, a short circuit fault, a DC bus capacitor health value, a filter condition, or one or more ground faults.

In some aspects, the techniques described herein relate to a method wherein extracting the one or more first features includes: determining, by the one or more processors, a thermal response rate for the first data associated with the inverter; determining, by the one or more processors, one or more cross sensor correlations based on the thermal response rate for the first data associated with the inverter; determining, by the one or more processors, one or more temperature differentials based on the one or more cross sensor correlations associated with the inverter; determining, by the one or more processors, a trend analysis for each of a plurality of sensors of the inverter based on the one or more temperature differentials associated with the inverter; and generating, by the one or more processors, the thermal health index based on one or more of the thermal response rate, the one or more cross sensor correlations, the one or more temperature differentials, or the trend analysis.

In some aspects, the techniques described herein relate to a method wherein determining the thermal response rate includes analyzing a multi-scale thermal response rate including delta temperature changes between case temperature and assembly temperature relative to switching frequency and DC current changes.

In some aspects, the techniques described herein relate to a method wherein determining the one or more cross sensor correlations includes analyzing horizontal sensor-to-sensor correlations and vertical stack-to-stack correlations.

In some aspects, the techniques described herein relate to a method wherein determining the one or more temperature differentials includes analyzing absolute temperature differentials between case to assembly, assembly to electronics and heat exchanger, and electronics to cabin and heat exchanger.

In some aspects, the techniques described herein relate to a method wherein extracting the one or more first features includes: determining, by the one or more processors, a temperature spread factor for the first data associated with the inverter; determining, by the one or more processors, a convergence quality score based on the temperature spread factor associated with the inverter; determining, by the one or more processors, one or more component response values based on the convergence quality score associated with the inverter; determining, by the one or more processors, a load impact for the inverter based on the one or more component response values associated with the inverter; and generating, by the one or more processors, the humidity health index based on one or more of the temperature spread factor, the convergence quality score, the one or more component response values, and the load impact associated with the inverter.

In some aspects, the techniques described herein relate to a method wherein generating the humidity health index does not include measuring one or more of a humidity value or one or more ambient conditions associated with one or more components of the inverter.

In some aspects, the techniques described herein relate to a method wherein determining the temperature spread factor includes analyzing an initial spread magnitude among case temperature, PCB temperature, and cabin temperature, and a rate of spread reduction.

In some aspects, the techniques described herein relate to a method wherein determining the convergence quality score includes analyzing uniformity of convergence, consistency of rates, and pattern stability.

In some aspects, the techniques described herein relate to a method further comprising: generating, by the one or more processors, a notification based on the determination that the data set meets the one or more threshold values; and outputting, by the one or more processors, the notification.

In some aspects, the techniques described herein relate to a method wherein the one or more operations of the inverter include one or more of outputting a notification, scheduling a maintenance request, preventing one or more actions associated with the inverter, or optimizing the one or more operations of the inverter.

In some aspects, the techniques described herein relate to a method wherein determining the one or more threshold values further includes determining the one or more threshold values based on one or more component-specific health scores.

In some aspects, the techniques described herein relate to a method for thermal health monitoring of an inverter in a battery energy storage system, the method comprising: determining, by one or more processors, a thermal response rate for operational data associated with the inverter using a multi-scale thermal response rate analysis; determining, by the one or more processors, one or more cross sensor correlations based on the thermal response rate using horizontal sensor-to-sensor analysis and vertical stack-to-stack analysis; determining, by the one or more processors, one or more temperature differentials based on the one or more cross sensor correlations; determining, by the one or more processors, a trend analysis for each of a plurality of sensors of the inverter based on the one or more temperature differentials; and generating, by the one or more processors, a thermal health index based on one or more of the thermal response rate, the one or more cross sensor correlations, the one or more temperature differentials, or the trend analysis associated with the inverter.

In some aspects, the techniques described herein relate to a method wherein the multi-scale thermal response rate analysis includes determining a delta temperature change between a case temperature and an assembly temperature relative to a switching frequency and a DC current change based on the operational data.

In some aspects, the techniques described herein relate to a method wherein determining the one or more temperature differentials includes determining one or more absolute temperature differentials between a case and an assembly, the assembly to a plurality of electronics and a heat exchanger, and the plurality of electronics to a cabin and the heat exchanger.

In some aspects, the techniques described herein relate to a method for training a machine learning model to predict a health of an inverter in a battery energy storage system, the method comprising: receiving, by one or more processors, first data regarding one or more element attributes associated with the inverter, wherein the first data includes a plurality of operational parameters; extracting, by the one or more processors, one or more first features from the first data based on analyzing processing algorithms identifying at least one of a thermal response pattern, an electrical parameter variation, or a component behavior signature; extracting, by the one or more processors, one or more second features from second data, wherein the second data includes one or more of an environmental condition, an operational loading pattern, a maintenance history record, or a component failure; training, by the one or more processors, the machine learning model to determine correlations between the one or more element attributes and one or more health assessment values based on the one or more first features and the one or more second features; and validating, by the one or more processors, the trained machine learning model using validation data to ensure accurate health predictions for operational inverter systems.

In some aspects, the techniques described herein relate to a method wherein the plurality of operational parameters include one or more of a plurality of DC bus voltage measurements, a plurality of multi-stack current readings, a plurality of three-phase AC measurements, a plurality of temperature monitoring data, or a plurality of component status indicators.

In some aspects, the techniques described herein relate to a method wherein the one or more health assessment values include one or more of a thermal health index, a humidity health index, or one or more component-specific health scores.

Additional objects and advantages of the disclosed embodiments will be set forth in part in the description that follows, and in part will be apparent from the description, or may be learned by practice of the disclosed embodiments. The objects and advantages of the disclosed embodiments will be realized and attained by means of the elements and combinations particularly pointed out in the appended claims.

It is to be understood that both the foregoing general description and the following detailed description are exemplary and explanatory only and are not restrictive of the disclosed embodiments, as claimed.

### BRIEF DESCRIPTION OF DRAWINGS

The accompanying drawings, which are incorporated in and constitute a part of this specification, illustrate various exemplary embodiments and together with the description, serve to explain the principles of the disclosed embodiments.

FIG. 1 depicts an exemplary system infrastructure for a battery, according to one or more embodiments.

FIG. 2 depicts a battery, according to one or more embodiments.

FIG. 3 depicts a controller, according to one or more embodiments.

FIG. 4 depicts a flow diagram for training a machine learning model, according to one or more embodiments.

FIG. 5 depicts a battery energy storage and power conversion system infrastructure, according to one or more embodiments.

FIG. 6 depicts a table showing sample data parameters from a power conversion system, according to one or more embodiments.

FIG. 7 depicts an exemplary flow diagram illustrating a health monitoring and control system, according to one or more embodiments.

FIG. 8 depicts an exemplary flow diagram for a health monitoring and control process, according to one or more embodiments.

FIG. 9 depicts an exemplary flow diagram for training the machine learning model of FIG. 8, according to one or more embodiments.

FIG. 10 depicts an exemplary flow diagram for determining a thermal health index, according to one or more embodiments.

### DETAILED DESCRIPTION

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of ±10% in the stated value. In this disclosure, unless stated otherwise, any numeric value may include a possible variation of ±10% in the stated value.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section.

Various embodiments of the present disclosure relate generally to systems and methods for battery energy storage system monitoring and control, and more particularly to machine learning-based predictive health assessment and fault detection for power conversion systems and transformers in battery energy storage systems.

Batteries may have a variety of shapes, also known as form factors. Common battery form factors include pouch-type, prismatic-type, and cylindrical-type. Pouch-type battery cells can be produced in various lengths and widths, which may enhance the battery capacity and allow optimization of battery cells. The flexible pouch-type battery can provide significant advantages over rigid battery formats, including improved mechanical flexibility that allows the battery to conform to curved or irregular surfaces in electronic devices. This flexibility enables manufacturers to integrate pouch-type batteries into compact spaces and unconventional form factors, such as wearable devices, smartphones with curved displays, and automotive applications where space constraints require batteries to fit around other components. The lightweight and thin profile of pouch-type batteries also facilitates easier incorporation into products where weight and thickness are critical design considerations, such as tablets, laptops, and electric vehicle applications. Additionally, the pouch format allows for more efficient use of available space within a device enclosure, as the flexible packaging can be shaped to increase energy density while reducing wasted volume compared to cylindrical or prismatic battery formats.

Prismatic battery cells offer may offer advantages in applications requiring efficient space utilization and thermal management. Their rectangular form factor allows for optimal packing density within battery modules and packs, reducing wasted space and enabling higher energy density per unit volume. The flat surfaces of prismatic cells may facilitate improved heat dissipation and thermal contact with cooling systems, which can enhance overall battery performance and safety. The outer shell of prismatic cells are typically made of aluminum alloy or steel, and are typically heavier than pouch-type battery cells, making them ideal for situations where weight is a less important design consideration.

Cylindrical battery cells may provide robust mechanical strength and proven manufacturing scalability that may benefit high-volume production applications. The cylindrical geometry distributes internal pressure more evenly during charging and discharging cycles, potentially contributing to enhanced structural integrity and longer cycle life. These cells may also offer advantages in automated manufacturing processes due to their uniform shape and established production techniques, which can result in consistent quality and cost-effective mass production. Cylindrical cells are typically heavier than prismatic cells, and further have reduced energy density, as packing the batteries together typically results in gaps or spaces between the cells that are not present in pouch and prismatic form factor designs.

Modules and packs can be produced in various designs to accommodate various products. Batteries may include one or more of a tab structure, a tab-less structure, or a jelly roll design. A tab-less jelly roll design may reduce resistance while increasing power output. A zig-zag stacking design may include cross-stacking technology that alternates cathode and anode sheets with separators, enhancing both precision and safety. A Cell Array Structure (CAS) structure for batteries may increase structural rigidity, enhance cooling efficiency, and ensure superior safety.

The assembly of the "cylindrical battery", the most commonly encountered battery form in our daily life, starts with "winding". Winding is a process where a machine called a winder rolls up the cathode and anode electrodes. This process has the advantage of being very fast, similar to how a "tissue roll" can quickly wrap the paper around the tissue core. During winding, cathode, anode, and separator rolls are unwound, and an aluminum tab is attached to the cathode's blank part while a copper tab is attached to the anode's blank part. Then they are attached to the winder in the order of cathode-separator-anode-separator, wound around a mandrel, like rolling toilet paper around its core, and then cut into an appropriate size to form a jelly roll.

Once the jelly roll is formed, it goes through various assembly processes to take the form of the familiar cylindrical battery. At first, the jelly roll produced by the winding method is inserted into a can so that the anode touches its bottom and the anode tab is bent at a 90-degree angle to make contact with the anode. After inserting the jelly roll into the can, it is attached using a resistance welding method. Resistance welding is also known as "spot welding" because bead-like spots are created when the metal melts and solidifies. After welding, a process called "beading" is used to create the neck of the cell, allowing the top cap to be fitted later.

Once the cylindrical shape of the battery is completed through beading, electrolyte is injected. To do this, a vacuum is created inside of the can and the electrolyte is injected into it through a nozzle. Then, the can is pressed to let the electrolyte fill the pores of the electrode. Once the electrolyte injection is complete, the cathode tab and the top cap are attached to the cell using laser welding. Finally, the cylindrical battery is completed by mechanically sealing it through the crimping and sizing processes, producing it to standardized dimensions. After the assembly process is completed, the battery undergoes cleaning, quality verification, and formation processes before being delivered to the customers.

Pouch-type batteries may be manufactured differently from cylindrical batteries. To place battery materials into the electrode pocket of a pouch case, a mono-cell is required. A mono-cell is the basic unit of a battery, consisting of a cathode, an anode, and two separators arranged in a layered structure, such as "separator - central electrode - separator - external electrode." The lamination and stacking processes are applied to this mono-cell. To be more specific, the process begins with lamination, a method for aligning and bonding the cathode, anode, and separator. This is followed by stacking, during which monocells are repeatedly layered. Finally, stacking half-cells - each made up of two separators and an anode - forms a cell stack, where the cathode and anode are alternately layered with separators in between. Lamination & stacking technology increases space efficiency within the pouch case, further enhancing energy density. Stacking, which involves individually layering battery cells, requires advanced technical expertise. By applying lamination & stacking, misalignment between cells is reduced, and empty spaces within the battery cell are eliminated, resulting in higher energy density. Lamination & stacking technology with mono-cells may be used to produce a range of pouch-type batteries, from ultra-thin batteries under 2mm to long cells.

The cell stack, produced through lamination and stacking, then moves to the packaging stage. First, leads are welded onto the cell stack, which comprises multiple layers of mono-cells. Next, a pouch film is compressed to form a pocket, and the lead-welded cell stack is inserted into this pouch pocket for assembly. To seal the pocket, heat and pressure are applied using a sealing tool.

During this process, two pockets are formed: the electrode pocket and the gas pocket. The electrode pocket houses the cell stack, including the cathode, anode, separator, and electrolyte. The gas pocket, meanwhile, serves as an entry for electrolyte injection and as a space to store gases generated during the injection process. After injecting the electrolyte into the gas pocket, the injection port is sealed with the sealing tool, completing the assembly of the pouch-type battery. In the following formation process, any unwanted gases that are generated and accumulated in the gas pocket are removed during the degassing stage by trimming the gas pocket.

Prismatic battery cell manufacturing may share some similarities with cylindrical cell production, while incorporating unique processes tailored to the rectangular form factor. The manufacturing process typically begins with electrode preparation, where cathode and anode materials are coated onto current collectors, similar to other battery types. However, prismatic cells may utilize either a winding process similar to cylindrical cells or a stacking process similar to pouch cells, depending on the specific design requirements and manufacturer preferences. The electrode assembly is then inserted into a rigid metal casing, which may be made of aluminum alloy or steel, providing structural integrity that differs from the flexible pouch format.

The assembly and sealing processes for prismatic cells may involve specialized techniques that accommodate the rectangular geometry and rigid housing. Electrolyte injection in prismatic cells may require precise control to ensure uniform distribution throughout the rectangular cell structure, which can be more challenging than the cylindrical geometry due to potential dead zones in corners. The sealing process typically involves laser welding or mechanical crimping of the metal casing, providing a hermetic seal that may offer enhanced safety compared to pouch cells but requires more complex manufacturing equipment than cylindrical cells. Quality control and formation processes for prismatic cells may need to account for the unique thermal and electrical characteristics of the rectangular form factor, potentially requiring different testing protocols compared to cylindrical or pouch cell manufacturing.

After completion of the formation and acquiring electrical characteristics, batteries are either delivered as individual cells or modularized to suit (or fit) electric vehicle models. The pack process involves modularizing the battery cells and placing them into packs before final delivery.

The first step in the pack process is to bundle battery cells to build a module. First, several surface-cleaned battery cells are arranged in a "cell to cell" configuration, which are retained into a module case with adhesives. Then bus bars and leads are welded to connect to the cells with a laser welder, and the module build is completed with installing module top cover. Finally, a pack build is completed when these modules are placed into the battery pack enclosures and connected each other. These complete battery packs are then installed in many applications such as electric vehicles and various IT devices. The number of cells and modules in a battery pack may vary, depending on the battery cells and application models.

Because a battery pack contains multiple cells or modules, balancing and managing these cells is critical, especially to accurately measure state of charge and optimize battery life. Therefore, once a pack is assembled, the battery is monitored, and its performance maintained in optimal conditions using a control system called BMS (Battery Management System), which estimates the battery's charging state and life. The CMS (Cell Monitoring System) inside the BMS measures the cells' condition and performs balancing to ensure optimal battery performance, safety, and life.

"Cell balancing" refers to adjusting the voltage differences between two or more serially connected cells. For instance, if two cells connected in series reach voltages of 4.2V and 4.0V, respectively, during charging, cell balancing adjusts this 0.2v difference to equalize the voltage. Voltage imbalance can occur due to manufacturing or external factors, and it can affect battery capacity and life, posing risks of overcharging, over-discharging, and fire hazards. Hence, cell balancing is essential.

Mobility and IT battery products have a wide variety of applications in IT devices such as smartphones and laptops, as well as LEVs (Light Electric Vehicles), electric bicycles, power tools, and wireless earphones. In general, energy is difficult to store and is lost after being used. Energy Storage Systems (ESS) are systems that store and manage energy so the energy can be used more efficiently. ESS has applications in power plants, power transmission and distribution facilities, homes, factories, and businesses. Through a system that is coupled with renewable energy, ESS can increase the efficiency of renewable energy and reduce electricity costs. ESS can also be used as backup power to reduce damages from power outages.

For example, solar modules installed on the roof of homes and ESS for uninterruptible power supply (UPS) in data centers store power and use the stored power during times of high demand or when electricity prices are high. In turn, ESS reduces damages from blackouts and saves electricity bills. Also, power plants can store and manage irregularly produced renewable energy, such as solar, wind, and hydroelectric power, which increases the efficiency of their use.

When used in conjunction with solar panel installations at home, ESS stores electricity produced by solar panels during daytime to be used at nighttime. A home battery may be a solution that can serve as an alternative energy source to reduce electricity costs and prepare for power outages. Installing ESS and solar power systems together generates power independently, increasing the self-consumption of power at home and reducing the overall electricity cost.

ESS for power grids, also commonly referred to as BESS, may be installed proximate to thermal power plants, solar and wind power plants, and substations. ESS for power grids has various applications in reducing power load, coupling with renewable power generation, and adjusting power frequency. Commercial ESS installed in commercial buildings such as offices, schools, factories, data centers, and the like may be used to reduce power load, or may be coupled with renewable power generation. ESS may include backup power solutions that protect facilities that require the constant supply of power, such as data centers and IT/telecommunications facilities. ESS may also be used to enable participation in an optimized energy marketplace, where excess power is sold back to the grid during peak hours and charged during off-peak hours. While BESS is ideal for use with renewable energy systems, BESS can store energy from many different sources, including energy generated by fossil fuels, hydropower, or any other power source that generates usable electricity.

An ESS is a system that stores electricity produced and supplies it when needed, thereby enhancing energy efficiency. It mainly includes four components: a battery, a power conversion system (PCS), a battery management system (BMS), and an energy management system (EMS). The PCS is a power conversion device that converts alternating current to direct current and vice versa. The BMS is a battery management system that typically monitors and/or controls one or more battery cells, packs, racks, and/or modules in the ESS, and includes safety features that stop charging and discharging if abnormalities in voltage, current, or temperature are detected. The EMS is a system that monitors the amount of electricity stored in the ESS and serves as a software responsible for the overall operation of the ESS.

There are three primary roles of ESS. First, it acts as an uninterrupted power supply in places where power outages must be avoided at all costs, such as hospitals and banks. In cases of power outages caused by typhoons or fires, it assists in power supply to prepare for large-scale blackout situations. Second, it stores generated energy and supplies it during peak power demand times. It helps to stabilize energy output by compensating for the inconsistent generation levels of new renewable energies such as solar and wind power. In homes, it can save on electricity bills by storing electricity during cheaper hours and using it during more expensive daytime hours. Third, it maintains the standard power frequency at 60 Hz in the power supply system, countering frequency fluctuations due to mismatches in supply and demand, thereby enhancing power quality.

A battery system may include controlling power to and from batteries and providing control signals. A battery energy storage system (BESS) may include a battery management system (BMS), a local energy management system (EMS), external data reporting, a power plant controller, a utility EMS, and fleet-level controls. The BMS may collect inputs from battery cells and modules, and may operate individual cells or groups of cells. The BMS may include a controller. The BMS may balance voltages in the battery cells, for example. The local EMS may collect information from the BMS, and may control the operations of the BMS at a system level. The EMS may determine available power and capacity of the BESS, for example. External data reporting may include components such as transformers, switchgear, or meters. The power plant controller may coordinate the local EMS with a supervisory system. The utility EMS may control an electrical grid connected to the BESS. The fleet-level controls may coordinate to operate multiple BESS’s at different locations. Communications between these components may be established wirelessly or through connected wires, depending on the system configuration and operational requirements.

BMS is a management system to monitor and control the status of batteries to operate them under optimal conditions. It measures the current, voltage, and temperature of batteries in Battery Electric Vehicles (BEVs) or Energy Storage Systems (ESS) with sensors, and identifies and controls potential concerns so that the batteries can maintain the highest performance possible. The location of the BMS can vary depending on the battery type or product.

The battery system includes the cell as the smallest unit, the module of a group of cells, and the pack of the final form of the battery. The role of BMS in a battery can be compared to that of a choir conductor. As a conductor sets the tone and tempo to combine different voices of the choir into a harmonious song, BMS tunes the current and voltage of each cell like a conductor.

BMS performs three main functions: monitoring, cell management, and control. Monitoring involves observing voltage, current, temperature, etc., through sensors in the battery system, and predicting state of charge (SoC) and the state of health (SoH) of the battery based on the data. Cell management refers to cell balancing, which reduces the voltage differences between battery cells to enhance energy efficiency and charging rate. Control is the process of regulating to prevent overcharging, overdischarging, and overcurrent in the battery. Ultimately, BMS plays a role in managing the life, performance, and safety of the battery, and as batteries continue to develop, BMS is also becoming more sophisticated and continues to evolve.

"C-rate" is a term one needs to know when dealing with fast charging speeds to the extent of acquiring special chargers and cables capable of rapid charging. Abbreviated from "current rate", the C-rate is a measure of the rate at which a battery is charged or discharged. It is also called "charge and discharge rates" and uses "C" as the unit, which is the abbreviation of "capacity". C-rate can be calculated by dividing the charging or discharging current (A) by the rated battery capacity (Ah). The standard C-rate is generally 1C.

Understanding the C-rate is very helpful when using batteries. First, the charge C-rates help users estimate how long it will take to fully charge their batteries. For example, when one sees a battery label that states, "Chargeable at 10C," it means the battery can be charged at a current of 10 times the battery capacity, and it takes at least 6 minutes to be completely charged.

On the other hand, the discharge C-rates help users predict the limits of product performance. For instance, a drone battery with a high discharge C-rate indicates a faster discharge rate, meaning it can perform complex maneuvers that require sudden high currents. Conversely, a low discharge C-rate could mean difficulty in performing high-performance actions that require high currents. Let us suppose that there is a drone battery with a discharge C-rate of 100C. The battery can supply a current of up to 100 times its capacity, but if the drone continues the move that requires that much power, it is discharged 100 times faster than the standard of an hour (3,600 seconds). Accordingly, it is discharged in just 36 seconds. As the use of batteries in our daily lives increases, and more products require fast charging or a sudden rush of high current, understanding the concept of C-rate will help us choose the right battery for each electronic device.

When we use portable electronic devices, we always check the battery's charge status. For instance, the battery icon on a phone shows percentages like 100%, 50%, 20%, etc. This indicator, showing how much percentage of the battery is left, is known as "SoC". Soc stands for "State of Charge". It represents the remaining battery capacity in percentage(%) which is the current usable battery capacity divided by the total capacity.

Accurate SoC measurement is a core competitive aspect for battery manufacturers. As such, there are various methods to measure SoC, including chemical, voltage, current integration, and pressure measurement methods. SoC is an element to provide convenience to users. Through SoC measurements, it is possible to determine how much longer the battery can be used more and users can determine when to charge and end the battery themselves, allowing them to use the device more efficiently. From the manufacturer's perspective, SoC is considered very important as it can enhance the stability of the battery. By setting the maximum charge of the battery lower than the highest point of the SoC and the minimum charge of the battery higher than the lowest point of the SoC, various problems such as safety issues due to overcharging and over-discharging of the battery can be prevented in advance. As a result, a more stable battery usage environment can be provided to users.

Batteries, like all other products, have a lifespan. The SoH (State of Health) is a useful indicator for the remaining life and the current state of batteries. It shows the battery's condition compared to its initial conditions at a glance. One can easily check the SoH on some smartphones, tablets, or laptops. Devices that do not provide SoH information, such as "maximum battery performance", can be assessed through specialized testing equipment. However, SoHs can vary even among batteries that have been used for the same period because battery life is affected by many factors, including user habits and the environment. In particular, if the electric vehicle battery is well managed, it is possible to drive the vehicle for 2 to 3 times longer than the manufacturer's warranty period with little decrease in SoH. SoH is referred to as "Maximum capacity" on some devices.

Recently, with many second-hand transactions taking place in real life, transactions of IT devices with batteries, such as smartphones and tablet PCs, are also increasing. At this time, SoH is a factor that must be checked to trade better products. Not only a second-hand transaction, but also an IT device with a built-in battery can be used more efficiently if the health status of the battery is checked with the SoH.

A cell is the basic unit of a battery. In devices requiring a lot of power, like electric vehicles, a battery pack contains numerous cells. However, even identical cells may develop voltage differences due to manufacturing processes or external factors. For example, when two cells connected in series are charged, the first cell could reach 4.2 V while the second cell stops at 4.0 V. Such imbalances between cells can affect battery capacity and life, and significantly increase the risk of safety issues due to overcharging and over-discharging. To prevent this, "cell balancing" is necessary.

Cell balancing adjusts and aligns the voltage differences between serially connected battery cells. It can be of two types: passive and active. Passive cell balancing dissipates the charging energy of a cell through a resistance to lower the cell voltage. In other words, it removes the charge from cells with more capacity by dissipating heat, making the charge of all cells uniform. While this method is simple and cost-effective, it is less energy-efficient as it wastes excess voltage and can only be applied during charging.

Active cell balancing transfers the charging energy from cells with higher voltage to those with lower voltage. It redistributes the charge to equalize the voltage between cells by providing more capacity to cells with less capacity. Unlike passive cell balancing, which dissipates heat, active balancing redistributes energy, making it more energy-efficient and faster in charging. While active cell balancing can be applied during both charging and discharging, it involves more complex additional circuitry and is thus more costly. Cell balancing happens in the BMS (Battery Management System), where the CMU (Cell Monitoring Unit) in the BMS measures the state of the cells and starts balancing, enabling safer use of the battery.

One or more embodiments may implement a dual-time-scale hybrid deep learning architecture (fast-scale ~5 ms, normal-scale 1s) with attention-based fusion for comprehensive power electronics health and thermal behavior monitoring. This framework may correlate high-frequency fault signatures with normal operational patterns to enable early detection of degradation in power stacks/IGBTs/MOSFETs, DC bus capacitors, AC filter, and overall inverter performance.

One or more embodiments may solve problems where current PCS systems lack comprehensive health predicting capabilities. Component failures may often be detected too late, leading to system downtime and incurring substantial service and other associated costs. Maintenance may typically be reactive rather than predictive. Most existing research solutions may be lab-only prototypes that typically cannot handle the limited real-world data available in field deployments.

A system may provide a prognosis solution for PCS systems that may be field-deployable. Current research solutions may be lab-only prototypes. Lab solutions may typically not handle the limited real-world data. One or more embodiments may use the existing hardware and communication channels with no additional hardware requirements. The system may provide comprehensive monitoring scope that may cover entire power components including power stacks with IGBTs or MOSFETs, capacitors, and filters.

One or more embodiments may provide temporal architecture that may operate in real time. The system may combine dual time-scale monitoring in PCS applications with attention-based fusion mechanism for correlating fast and slow phenomena. The system may provide integration of multiple monitoring parameters in a single cohesive framework and may offer practical field deployable solution for PCS health monitoring in BESS.

One or more embodiments may implement temperature predictive analytics using an algorithm (e.g., HEAT (Hierarchical Evaluation & Analysis of Thermal-patterns). The algorithm may perform multi-scale thermal response rate analysis to determine one or more correlations and determining outputs are within predefined thresholds. The algorithm may perform cross sensor correlations horizontally from sensor to sensor and vertically from stack to stack based on predefined thresholds. The algorithm may analyze temperature differentials including case to assembly, assembly to electronics and heat exchanger, and electronics to cabin and heat exchanger based on predefined thresholds.

The system may perform statistics analysis for each sensor including rolling average (e.g., 1 min, 10 min, 1 hour), min/max, standard deviation, based on predefined thresholds, and trend analysis. One or more embodiments may collect daily statistics and may create a Thermal Health Index (THI) percentage using multi-scale thermal response rate analysis, cross sensor correlations, temperature differentials, and statistics in real-time.

One or more embodiments may implement humidity predictive analytics using an algorithm (e.g., HUMID (Heat-based Utility for Moisture Identification and Detection). Since PCS may generally lack humidity sensors, this algorithm may behave as a virtual humidity sensor. One or more embodiments may analyze a temperature spread factor including initial spread magnitude among case, PCB & cabin, a rate of spread reduction, and a pattern of reduction. One or more embodiments may analyze convergence quality including uniformity of convergence, consistency of rates, and pattern stability.

The system may analyze component response including relative cooling rates and component temperature relationships. One or more embodiments may analyze load impact including duration of low load and load stability. The system may collect daily statistics and may create a Humidity Health Index (HHI) percentage using temperature spread factor, convergence quality, component response, and load impact in real-time. The system may include no additional sensors, no humidity measurement, and no ambient condition monitoring. One or more embodiments may provide a global application with climate-independent operation and no local adjustments needed. One or more embodiments may provide energy efficiency by activating only when truly needed with precise risk discrimination. One or more embodiments may provide early detection that may catch risks at formation with proactive protection.

One or more embodiments may implement other predictive analytics algorithms including DC overcurrent, open phase faults, gate driver faults, short circuit faults, DC bus capacitor health, filter conditions, and ground faults. Each algorithm may operate independently but may contribute to a unified system health assessment.

One or more embodiments may implement advanced inverter learning for algorithmic system-health using an input layer with algorithm outputs including HEAT (Thermal Health Analytics), HUMID (Moisture Detection), DC Overcurrent Protection, Open Circuit Detection, Gate Driver Monitoring, Short Circuit Protection, DC Bus Capacitor Health, Filter Condition Analysis, Ground faults, and Efficiency tracking.

The system may implement an inverter encoder layer with multi-head attention including algorithm-specific attention weights, cross-algorithm pattern recognition, and temporal relationship learning. One or more embodiments may provide pattern recognition including fault signature identification, anomaly detection, and system behavior learning. The system may provide cross-algorithm learning including inter-algorithm correlations and cascading effect analysis.

One or more embodiments may implement an output layer with system intelligence including health assessment with overall system health index, component-specific health scores, and risk level classification. The system may provide predictive analytics including early fault warnings, failure progression prediction, and time-to-maintenance estimation. The system may provide action recommendations including maintenance scheduling, preventive actions, and operation optimization. One or more embodiments may provide real-time processing features including less than approximately one minute execution cycle, dynamic threshold adjustment, continuous learning capability, adaptive response system, and system-wide pattern detection.

One or more embodiments may optimize the operation of power conversion systems (inverters), transformers, battery management systems, thermal sensors, IGBT switches, DC bus capacitors, and cooling systems by implementing machine learning algorithms that monitor real-time conditions and predict component health. One or more embodiments may enhance the performance of temperature sensors, current sensors, voltage sensors, and insulation monitoring devices by providing predictive analytics that enable proactive maintenance and optimal operating parameter adjustments.

The system may reduce thermal stress on IGBT switches and power electronics by analyzing thermal response rates and temperature differentials to prevent overheating conditions. One or more embodiments may reduce electrical stress on DC bus capacitors and power stacks by monitoring overcurrent conditions and implementing protective measures before damage occurs. One or more embodiments may reduce mechanical stress on cooling systems and fans by optimizing their operation based on predictive thermal models rather than reactive temperature thresholds.

Implementing predictive health monitoring may improve the lifetime and reliability of battery cells by preventing overcharging, over-discharging, and thermal runaway conditions. One or more embodiments may enhance the reliability of power conversion system components including IGBT switches, capacitors, and filters by detecting early-stage degradation patterns and scheduling preventive maintenance. One or more embodiments may extend transformer life by monitoring insulation resistance degradation and partial discharge activity to prevent catastrophic failures.

One or more embodiments may enable power conversion systems to operate at higher efficiency levels by optimizing switching frequencies and load management based on real-time thermal and electrical conditions. One or more embodiments may allow transformers to operate closer to their rated capacity by providing continuous health monitoring that ensures safe operation within design limits. One or more embodiments enable battery systems to achieve faster charging rates by implementing advanced thermal management algorithms that prevent overheating during high-current operations.

The system may reduce energy consumption by optimizing cooling system operation through predictive thermal management, activating cooling only when needed rather than continuously. One or more embodiments may reduce communication overhead by implementing efficient data processing algorithms that reduce the frequency of sensor polling and data transmission. One or more embodiments may reduce overall system energy consumption by optimizing power conversion efficiency and reducing parasitic losses through intelligent control algorithms.

One or more embodiments may reduce costs by enabling the use of standard temperature sensors instead of specialized humidity sensors while still achieving moisture detection capabilities through advanced analytics. One or more embodiments may allow the use of fewer monitoring devices by implementing cross-sensor correlation algorithms that can detect faults using existing sensor infrastructure. One or more embodiments may reduce the need for expensive specialized monitoring equipment by leveraging machine learning algorithms that can detect component degradation using standard operational data from existing sensors and control systems.

One or more embodiments may include a dual-time-scale hybrid deep learning architecture with attention-based fusion for comprehensive power electronics health monitoring. This architecture may provide an improvement in the functioning of the hardware performance of a computer by implementing real-time processing features including 1-minute execution cycle, dynamic threshold adjustment, continuous learning capability, and adaptive response system that optimize controller operations.

Energy efficiency algorithms may be implemented and activated only when truly needed with precise risk discrimination. These algorithms may provide an improvement in the functioning of the hardware performance of a computer by reducing energy consumption through optimized cooling system operation and implementing efficient data processing algorithms that may reduce the frequency of sensor polling and data transmission.

One or more embodiments may include an inverter encoder layer with multi-head attention including algorithm-specific attention weights and cross-algorithm pattern recognition. This architecture may provide an improvement in the functioning of the hardware performance of a computer by enabling distributed processing across multiple monitoring algorithms that operate independently while contributing to a unified system health assessment. One or more comprehensive fault detection algorithms may include DC overcurrent, open phase faults, gate driver faults, short circuit faults, and ground faults. These algorithms may provide an improvement in the functioning of the hardware performance of a computer by implementing early detection capabilities that catch risks at formation with proactive protection and fault tolerance mechanisms.

One or more embodiments may include predictive analytics algorithms that may analyze battery cell conditions and perform balancing to ensure optimal battery performance. These algorithms may provide an improvement in technology by implementing machine learning models that estimate state of charge and state of health with enhanced accuracy through correlation analysis and temporal tracking capabilities. One or more cross sensor correlation algorithms may analyze horizontal sensor-to-sensor correlations and vertical stack-to-stack correlations. These algorithms may provide an improvement in technology by compensating for sensor variations and reducing measurement noise through multi-scale thermal response rate analysis and statistical processing including rolling averages and standard deviation calculations.

One or more embodiments may include virtual humidity sensing capabilities through the HUMID algorithm that behaves as a virtual humidity sensor without requiring additional humidity measurement hardware. This algorithm may provide an improvement in technology by achieving moisture detection capabilities through advanced analytics using existing temperature sensors, thereby improving measurement precision without requiring new sensors.

One or more embodiments may include comprehensive health monitoring algorithms that detect early-stage degradation patterns in power conversion systems and transformers. These algorithms may provide an improvement in technology by enabling early fault detection through analysis of insulation resistance degradation patterns, partial discharge activity, and thermal stress indicators before component failures occur. One or more embodiments may include optimization algorithms that control switching frequencies and load management based on real-time thermal and electrical conditions. These algorithms may provide an improvement in technology by enabling power conversion systems to operate at higher efficiency levels and allowing battery systems to achieve faster charging rates through advanced thermal management.

One or more embodiments may include predictive health monitoring algorithms that prevent overcharging, over-discharging, and thermal runaway conditions. These algorithms may provide an improvement in technology by extending battery cell lifetime and reliability through proactive maintenance scheduling and preventive actions that reduce component stress and degradation. One or more embodiments may include cell balancing algorithms that adjust voltage differences between serially connected battery cells through active and passive balancing techniques. These algorithms may provide an improvement in technology by enhancing balancing efficiency through precise voltage equalization that reduces energy loss and improves charging time while maintaining cell uniformity.

One or more embodiments may include adaptive response systems with continuous learning capability that provide smooth transitions between operating states. These systems may provide an improvement in technology by implementing dynamic threshold adjustment and system-wide pattern detection that enable safer state transitions during normal, fault, and recovery operations. The system may include advanced thermal management algorithms that prevent overheating during high-current operations and extreme conditions. These algorithms may provide an improvement in technology by implementing predictive thermal models that optimize cooling system operation and provide enhanced safety during fast charging, cold starts, and high-load operations.

One or more embodiments may include machine learning models trained to determine correlations between element attributes and health assessment values. These models may provide an improvement in technology by enhancing simulation and modeling capabilities through failure progression prediction, time-to-maintenance estimation, and system behavior learning that improve performance predictions. Predictive analytics algorithms may be included to analyze component degradation patterns and failure modes. These algorithms may provide an improvement in technology by providing better predictions of degradation, capacity fade, and failure modes through temporal relationship learning, anomaly detection, and cascading effect analysis of system hardware.

The system may include communication interfaces and data processing systems that enable integration with external systems. These systems may provide an improvement in technology by improving interoperability with power plant controllers, utility energy management systems, and fleet-level controls through standardized communication protocols and data exchange capabilities. One or more embodiments may include efficient data processing algorithms and communication optimization features. These features may provide an improvement in technology by improving cybersecurity and communication robustness through reduced data transmission overhead, optimized sensor polling frequencies, and enhanced data integrity mechanisms that reduce packet loss and latency.

One or more embodiments may include comprehensive diagnostic algorithms that provide component-specific health scores and risk level classification. These algorithms may provide an improvement in technology by improving usability of diagnostic tools for engineers through faster root cause analysis, predictive maintenance scheduling, and detailed fault signature identification that accelerate troubleshooting and maintenance planning.

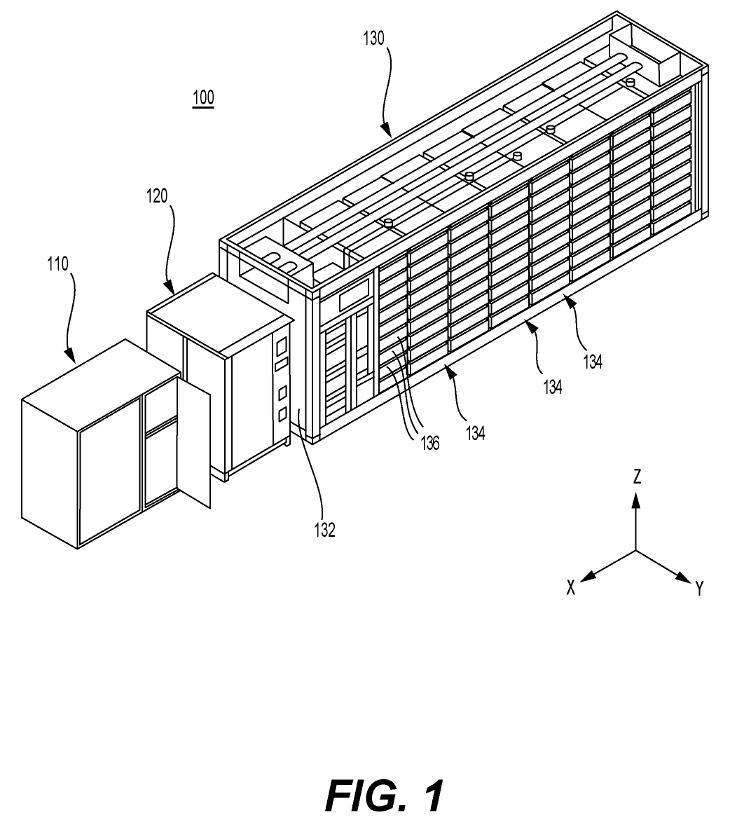

FIG. 1 depicts an exemplary battery system infrastructure, according to one or more embodiments. Battery energy storage system 100 may include battery control 110, battery thermal protection 120, and battery array 130. Battery array 130 may include housing 132 and battery rack 134 (e.g., one or more battery racks, eight battery racks).

Housing 132 may be a battery frame, for example. Battery rack 134 may include battery module 136 (e.g., one or more battery modules, nine battery modules). Battery module 136 may include one or more battery cells in a module case. Battery module 136 may be stacked in a direction, for example, in a vertical direction as battery rack 134. Battery rack 134 may include a rack case to facilitate stacking the battery module 136. Each battery module 136 may be received in a receiving space of the rack case as a module stack. One module stack may constitute one of battery rack 134. Alternatively, two or more module stacks may constitute one of battery rack 134.

Battery module 136 included in the battery rack 134 may further include a control unit such as a battery management system (BMS) for each battery module or each predetermined group. For example, each battery module 136 may include a pack BMS. A battery module 136 including a pack BMS may be referred to as a battery pack. For example, the battery rack 134 may include a plurality of battery packs. Alternatively, a battery pack assembly may include one or more battery cells with a module-less design, such as a direct cell-to-pack design, for example.

The battery rack 134 may be arranged in at least one direction, for example, a horizontal direction. For example, battery array 130 may include eight battery racks of battery rack 134 that may be arranged in the left-right direction (X-axis direction) in battery array 130. Each battery rack 134 may have a control unit, for example, a rack BMS. The rack BMS may be connected to the plurality of pack BMSs included in battery rack 134 to transmit and receive data to and from the plurality of pack BMSs and control them.

The rack BMS may be connected to a control device, for example, battery control 110. Battery rack 134 may include an integrated control unit such as, for example, a battery processing unit (BPU) which may perform communications or control operations with the plurality of rack BMSs.

Housing 132 may be a container housing. Housing 132 may have an empty internal space. Housing 132 may accommodate the battery rack 134 in the internal space. More specifically, as depicted in FIG. 1, housing 132 may be formed in the shape of an approximately rectangular prism. Housing 132 may include an upper housing, a lower housing, a front housing, a rear housing, a left housing, and a right housing with respect to the internal space. Housing 132 may accommodate the battery rack 134 in the internal space defined by these six unit housings.

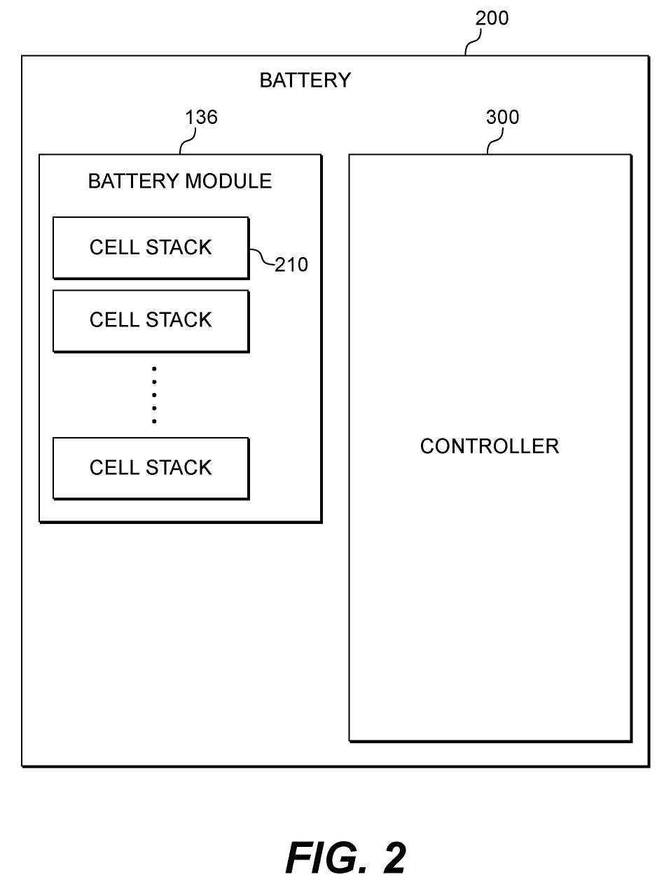

FIG. 2 depicts a battery, according to one or more embodiments. Battery 200 may include a battery module 136 and controller 300. Battery module 136 may include a plurality of cell stacks, including cell stack 210.

Battery 200 may include a battery pack. Battery 200 may include an overcharge prevention apparatus. Overcharge prevention apparatus may include a voltage measuring unit, a current regulating unit, a controller 300, and optionally may further include at least one of a disconnecting unit, a current measuring unit, and a cooling unit. Additionally, when the overcharge prevention apparatus includes a disconnecting unit, a discharge inducing unit may be included.

The plurality of cell stacks, which may include cell stack 210, may be connected in series and installed on a high current path between two power terminals of battery 200. A voltage measuring unit may measure the voltage of each cell stack 210, and may generate a first monitoring signal indicating the measured voltage. The first monitoring signal generated by the voltage measuring unit may be transmitted to the controller. The current regulating unit may be configured to selectively provide each cell stack 210 with bypass paths connected in parallel. Current regulating unit may provide bypass paths individually to the plurality of cell stacks, which may include for example cell stack 210.

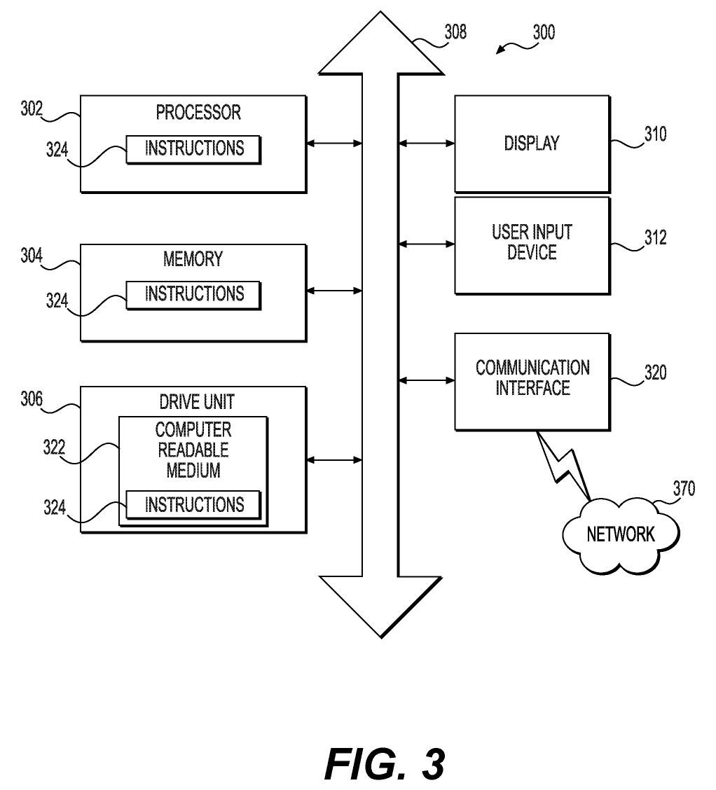

FIG. 3 depicts a controller, according to one or more embodiments. FIG. 3 and the following discussion provide a brief, general description of a suitable computing environment in which the present disclosure may be implemented. In one embodiment, any of the disclosed systems, methods, and/or graphical user interfaces may be executed by or implemented by a computing system consistent with or similar to that depicted in FIG. 3. Although not required, aspects of the present disclosure are described in the context of computer-executable instructions, such as routines executed by a data processing device, e.g., a server computer, wireless device, and/or personal computer. Those skilled in the relevant art will appreciate that aspects of the present disclosure can be practiced with other communications, data processing, or computer system configurations, including: Internet appliances, hand-held devices (including personal digital assistants (“PDAs”)), wearable computers, all manner of cellular or mobile phones (including Voice over IP (“VoIP”) phones), dumb terminals, media players, gaming devices, virtual reality devices, multi-processor systems, microprocessor-based or programmable consumer electronics, set-top boxes, network PCs, mini-computers, mainframe computers, and the like. Indeed, the terms “computer,” “server,” and the like, are generally used interchangeably herein, and refer to any of the above devices and systems, as well as any data processor.

Aspects of the present disclosure may be embodied in a special purpose computer and/or data processor that is specifically programmed, configured, and/or constructed to perform one or more of the computer-executable instructions explained in detail herein. While aspects of the present disclosure, such as certain functions, are described as being performed exclusively on a single device, the present disclosure may also be practiced in distributed environments where functions or modules are shared among disparate processing devices, which are linked through a communications network, such as a Local Area Network (“LAN”), Wide Area Network (“WAN”), and/or the Internet. Similarly, techniques presented herein as involving multiple devices may be implemented in a single device. In a distributed computing environment, program modules may be located in both local and/or remote memory storage devices.

Aspects of the present disclosure may be stored and/or distributed on non-transitory computer-readable media, including magnetically or optically readable computer discs, hard-wired or preprogrammed chips (e.g., EEPROM semiconductor chips), nanotechnology memory, biological memory, or other data storage media. Alternatively, computer implemented instructions, data structures, screen displays, and other data under aspects of the present disclosure may be distributed over the Internet and/or over other networks (including wireless networks), on a propagated signal on a propagation medium (e.g., an electromagnetic wave(s), a sound wave, etc.) over a period of time, and/or they may be provided on any analog or digital network (packet switched, circuit switched, or other scheme).

The controller 300 may include a set of instructions that can be executed to cause the controller 300 to perform any one or more of the methods or computer-based functions disclosed herein. The controller 300 may operate as a standalone device or may be connected, e.g., using a network, to other computer systems or peripheral devices.

In a networked deployment, the controller 300 may operate in the capacity of a server or as a client in a server-client user network environment, or as a peer computer system in a peer-to-peer (or distributed) network environment. The controller 300 can also be implemented as or incorporated into various devices, such as a personal computer (PC), a tablet PC, a set-top box (STB), a personal digital assistant (PDA), a mobile device, a palmtop computer, a laptop computer, a desktop computer, a communications device, a wireless telephone, a land-line telephone, a control system, a camera, a scanner, a facsimile machine, a printer, a pager, a personal trusted device, a web appliance, a network router, switch or bridge, or any other machine capable of executing a set of instructions (sequential or otherwise) that specify actions to be taken by that machine. In a particular implementation, the controller 300 can be implemented using electronic devices that provide voice, video, or data communication. Further, while the controller 300 is illustrated as a single system, the term “system” shall also be taken to include any collection of systems or sub-systems that individually or jointly execute a set, or multiple sets, of instructions to perform one or more computer functions.

As illustrated in FIG. 3, the controller 300 may include a processor 302, e.g., a central processing unit (CPU), a graphics processing unit (GPU), or both. The processor 302 may be a component in a variety of systems. For example, the processor 302 may be part of a standard computer. The processor 302 may be one or more general processors, digital signal processors, application specific integrated circuits, field programmable gate arrays, servers, networks, digital circuits, analog circuits, combinations thereof, or other now known or later developed devices for analyzing and processing data. The processor 302 may implement a software program, such as code generated manually (i.e., programmed).

The controller 300 may include a memory 304 that can communicate via a bus 308. The memory 304 may be a main memory, a static memory, or a dynamic memory. The memory 304 may include, but is not limited to computer readable storage media such as various types of volatile and non-volatile storage media, including but not limited to random access memory, read-only memory, programmable read-only memory, electrically programmable read-only memory, electrically erasable read-only memory, flash memory, magnetic tape or disk, optical media, and the like. In one implementation, the memory 304 includes a cache or random-access memory for the processor 302. In alternative implementations, the memory 304 is separate from the processor 302, such as a cache memory of a processor, the system memory, or other memory. The memory 304 may be an external storage device or database for storing data. Examples include a hard drive, compact disc (“CD”), digital video disc (“DVD”), memory card, memory stick, floppy disc, universal serial bus (“USB”) memory device, or any other device operative to store data. The memory 304 is operable to store instructions executable by the processor 302. The functions, acts or tasks illustrated in the figures or described herein may be performed by the processor 302 executing the instructions stored in the memory 304. The functions, acts or tasks are independent of the particular type of instructions set, storage media, processor or processing strategy and may be performed by software, hardware, integrated circuits, firm-ware, micro-code, and the like, operating alone or in combination. Likewise, processing strategies may include multiprocessing, multitasking, parallel processing, and the like.

As shown, the controller 300 may further include a display 310, such as a liquid crystal display (LCD), an organic light emitting diode (OLED), a flat panel display, a solid-state display, a cathode ray tube (CRT), a projector, a printer or other now known or later developed display device for outputting determined information. The display 310 may act as an interface for the user to see the functioning of the processor 302, or specifically as an interface with the software stored in the memory 304 or in the drive unit 306.

Additionally or alternatively, the controller 300 may include an input device 312 configured to allow a user to interact with any of the components of controller 300. The input device 312 may be a number pad, a keyboard, or a cursor control device, such as a mouse, or a joystick, touch screen display, remote control, or any other device operative to interact with the controller 300.

The controller 300 may also or alternatively include drive unit 306 implemented as a disk or optical drive. The drive unit 306 may include a computer-readable medium 322 in which one or more sets of the instructions 324, e.g., software, can be embedded. Further, the instructions 324 may embody one or more of the methods or logic as described herein. The instructions 324 may reside completely or partially within the memory 304 and/or within the processor 302 during execution by the controller 300. The memory 304 and the processor 302 also may include computer-readable media as discussed above.

In some systems, a computer-readable medium 322 includes instructions 324 or receives and executes instructions 324 responsive to a propagated signal so that a device connected to a network 370 can communicate voice, video, audio, images, or any other data over the network 370. Further, the instructions 324 may be transmitted or received over the network 370 via a communication port or interface 320, and/or using a bus 308. The communication port or interface 320 may be a part of the processor 302 or may be a separate component. The communication port or interface 320 may be created in software or may be a physical connection in hardware. The communication port or interface 320 may be configured to connect with a network 370, external media, the display 310, or any other components in controller 300, or combinations thereof. The connection with the network 370 may be a physical connection, such as a wired Ethernet connection or may be established wirelessly as discussed below. Likewise, the additional connections with other components of the controller 300 may be physical connections or may be established wirelessly. The network 370 may alternatively be directly connected to a bus 308.

While the computer-readable medium 322 is shown to be a single medium, the term "computer-readable medium" may include a single medium or multiple media, such as a centralized or distributed database, and/or associated caches and servers that store one or more sets of instructions. The term "computer-readable medium" may also include any medium that is capable of storing, encoding, or carrying a set of instructions for execution by a processor or that cause a computer system to perform any one or more of the methods or operations disclosed herein. The computer-readable medium 322 may be non-transitory, and may be tangible.

The computer-readable medium 322 can include a solid-state memory such as a memory card or other package that houses one or more non-volatile read-only memories. The computer-readable medium 322 can be a random-access memory or other volatile re-writable memory. Additionally or alternatively, the computer-readable medium 322 can include a magneto-optical or optical medium, such as a disk or tapes or other storage device to capture carrier wave signals such as a signal communicated over a transmission medium. A digital file attachment to an e-mail or other self-contained information archive or set of archives may be considered a distribution medium that is a tangible storage medium. Accordingly, the disclosure is considered to include any one or more of a computer-readable medium or a distribution medium and other equivalents and successor media, in which data or instructions may be stored.

In an alternative implementation, dedicated hardware implementations, such as application specific integrated circuits, programmable logic arrays and other hardware devices, can be constructed to implement one or more of the methods described herein. Applications that may include the apparatus and systems of various implementations can broadly include a variety of electronic and computer systems. One or more implementations described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

The controller 300 may be connected to a network 370. The network 370 may define one or more networks including wired or wireless networks. The wireless network may be a cellular telephone network, an 802.11, 802.16, 802.20, or WiMAX network. Further, such networks may include a public network, such as the Internet, a private network, such as an intranet, or combinations thereof, and may utilize a variety of networking protocols now available or later developed including, but not limited to TCP/IP based networking protocols. The network 370 may include wide area networks (WAN), such as the Internet, local area networks (LAN), campus area networks, metropolitan area networks, a direct connection such as through a Universal Serial Bus (USB) port, or any other networks that may allow for data communication. The network 370 may be configured to couple one computing device to another computing device to enable communication of data between the devices. The network 370 may generally be enabled to employ any form of machine-readable media for communicating information from one device to another. The network 370 may include communication methods by which information may travel between computing devices. The network 370 may be divided into sub-networks. The sub-networks may allow access to all of the other components connected thereto or the sub-networks may restrict access between the components. The network 370 may be regarded as a public or private network connection and may include, for example, a virtual private network or an encryption or other security mechanism employed over the public Internet, or the like.

In accordance with various implementations of the present disclosure, the methods described herein may be implemented by software programs executable by a computer system. Further, in an exemplary, non-limited implementation, implementations can include distributed processing, component/object distributed processing, and parallel processing. Alternatively, virtual computer system processing can be constructed to implement one or more of the methods or functionality as described herein.

Although the present specification describes components and functions that may be implemented in particular implementations with reference to particular standards and protocols, the disclosure is not limited to such standards and protocols. For example, standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same or similar functions as those disclosed herein are considered equivalents thereof.

It will be understood that the steps of methods discussed are performed in one embodiment by an appropriate processor (or processors) of a processing (i.e., computer) system executing instructions (computer-readable code) stored in storage. It will also be understood that the disclosure is not limited to any particular implementation or programming technique and that the disclosure may be implemented using any appropriate techniques for implementing the functionality described herein. The disclosure is not limited to any particular programming language or operating system.

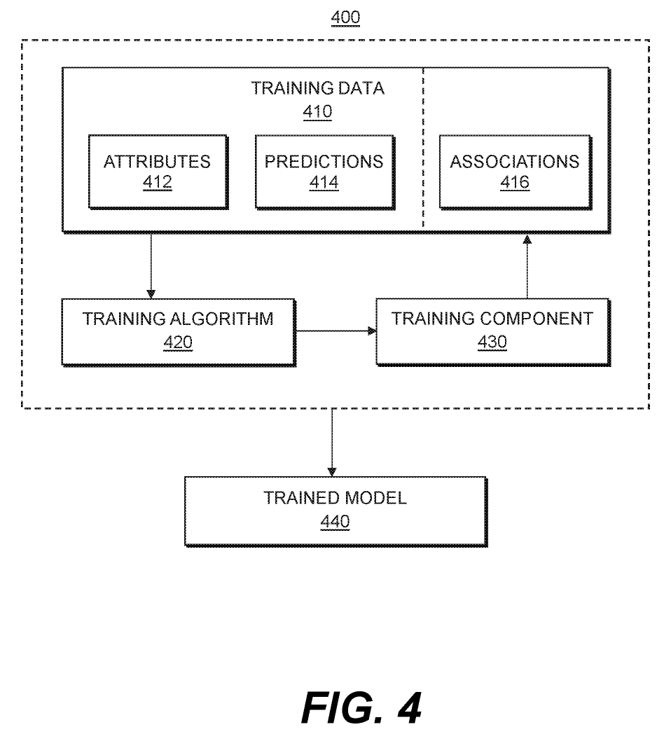

FIG. 4 depicts a flow diagram for training a machine learning model, according to one or more embodiments. As disclosed herein, one or more implementations disclosed herein may be applied by using a machine learning model. A machine learning model as disclosed herein may be trained using one or more components or operations. As depicted in flow diagram 400 of FIG. 4, training data 410 may include one or more of attributes 412 and predictions 414 related to a machine learning model to be trained. The attributes 412 may be from any applicable source including a component, attribute of a component, extracted feature, or set shown in the figures provided herein. The predictions 414 may be included for machine learning models generated based on supervised or semi-supervised training. An unsupervised machine learning model might not be trained using predictions 414. Predictions 414 may include known or desired outputs for future inputs similar to or in the same category as attributes 412 that do not have corresponding known outputs.

The training data 410 and a training algorithm 420 may be provided to a training component 430 that may apply the training data 410 to the training algorithm 420 to generate a trained machine learning model 440. The training component 430 may be provided associations 416 that compare a previous output of the corresponding machine learning model to apply the previous result to re-train the machine learning model. The associations 416 may be used by the training component 430 to update the corresponding machine learning model. The training algorithm 420 may utilize machine learning networks and/or models including, but not limited to a deep learning network such as Deep Neural Networks (DNN), Convolutional Neural Networks (CNN), Fully Convolutional Networks (FCN) and Recurrent Neural Networks (RCN), probabilistic models such as Bayesian Networks and Graphical Models, and/or discriminative models such as Decision Forests and maximum margin methods, or the like.

A machine learning model disclosed herein may be trained by adjusting one or more weights, layers, and/or biases during a training phase. During the training phase, historical or simulated data may be provided as inputs to the model. The model may adjust one or more of its weights, layers, and/or biases based on such historical or simulated information. The adjusted weights, layers, and/or biases may be configured in a production version of the machine learning model (e.g., a trained model) based on the training. Once trained, the machine learning model may output machine learning model outputs in accordance with the subject matter disclosed herein. One or more machine learning models disclosed herein may continuously update based on feedback associated with use or implementation of the machine learning model outputs.

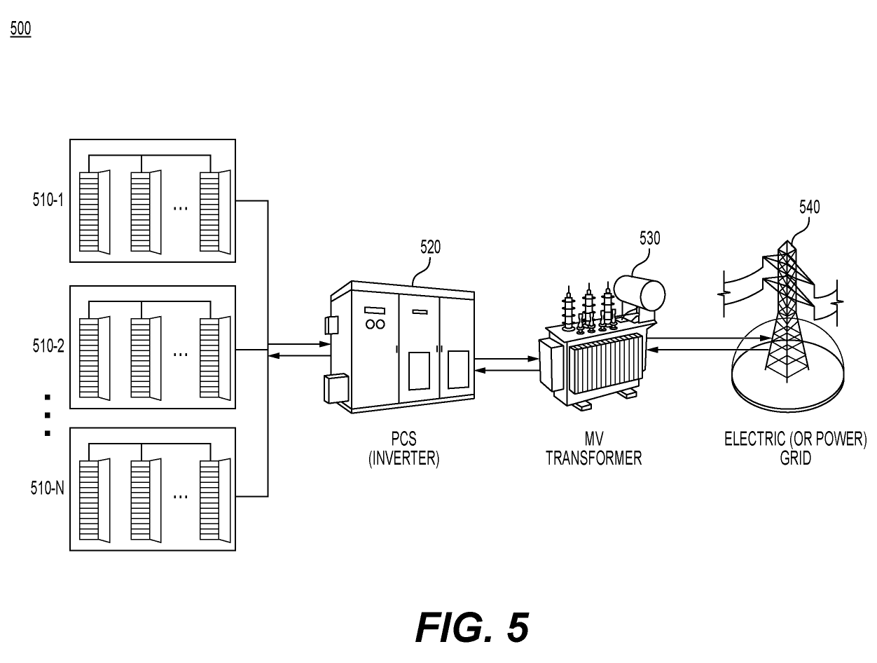

FIG. 5 depicts a battery energy storage and power conversion system infrastructure, according to one or more embodiments. The system 500 may comprise a battery array including a first battery 510-1, a second battery 510-2, and an nth battery 510-N arranged in a parallel configuration. The battery array may be connected to an inverter 520, which may serve as a power conversion system that manages the conversion between DC and AC power. The inverter 520 may be connected to a transformer 530, which may step up or step down the voltage as needed for grid connection. The transformer 530 may be connected to an electric grid 540, which may receive power from or provide power to the system 500.

The first battery 510-1, the second battery 510-2, and the nth battery 510-N may represent a plurality of battery units or battery racks that may provide DC power to the inverter 520. Each of the first battery 510-1, the second battery 510-2, and the nth battery 510-N may include one or more battery modules similar to the battery module 136 described with reference to FIG. 1. The battery array configuration may enable scalable energy storage capacity by adding or removing individual battery units as needed for specific applications.

The inverter 520 may function as a power conversion system that may convert DC power from the battery array to AC power for transmission to the electric grid 540. The inverter 520 may include specific hardware components including IGBTs (Insulated Gate Bipolar Transistors) or MOSFETs (Metal-Oxide-Semiconductor Field-Effect Transistors) that may perform the switching operations for power conversion. The inverter 520 may further include DC bus capacitors that may store energy and provide voltage stability during power conversion operations. AC filters may be included in the inverter 520 to reduce harmonic distortion and ensure power quality compliance for grid connection.

The system 500 may enable bidirectional power flow, allowing the battery array to be charged from the electric grid 540 through the transformer 530 and the inverter 520, or to discharge power back to the electric grid 540 through the same components. During charging operations, AC power from the electric grid 540 may be stepped down by the transformer 530 and converted to DC power by the inverter 520 for storage in the battery array. During discharging operations, DC power from the battery array may be converted to AC power by the inverter 520 and stepped up by the transformer 530 for transmission to the electric grid 540.

The system 500 may provide comprehensive monitoring capabilities through the implementation of a machine learning model that may implement a dual-time-scale hybrid deep learning architecture. For example, the dual-time-scale hybrid deep learning may include a fast-scale processing at approximately 5 millisecond intervals. In addition, the dual-time-scale hybrid deep learning may include a normal-scale processing at approximately 1 second intervals. This architecture may enable the system 500 to monitor high-frequency fault signatures in the inverter 520 components while simultaneously tracking normal operational patterns over longer time scales. The system 500 may utilize attention-based fusion mechanisms for correlating high-frequency fault signatures with normal operational patterns in power electronics monitoring of the inverter 520.

One or more processors of the controller 300 may receive a data set associated with the inverter 520 of the system 500. The data set may include operational parameters from the inverter 520 such as DC bus voltage measurements, DC current measurements for individual power stacks, AC current measurements for each phase, temperature readings from IGBT or MOSFET components, and status indicators for various breakers and contactors within the inverter 520.

The inverter health monitoring system may utilize one or more measurement methodologies by processing real-time operational parameters to assess the health of the inverter 520 through direct sensor monitoring within the power conversion system of the battery energy storage system 500. The one or more processors may receive operational data from the inverter 520 including DC bus voltage measurements, multi-stack current readings, temperature parameters from IGBT components, and status indicators from various breakers and contactors. The operational data may include voltage and current parameters, thermal measurements, and component status information that may indicate the operational status and health condition of the inverter 520. This direct monitoring approach may provide comprehensive inverter health assessment utilizing existing sensor infrastructure within the system 500 to enable predictive maintenance and fault detection capabilities.

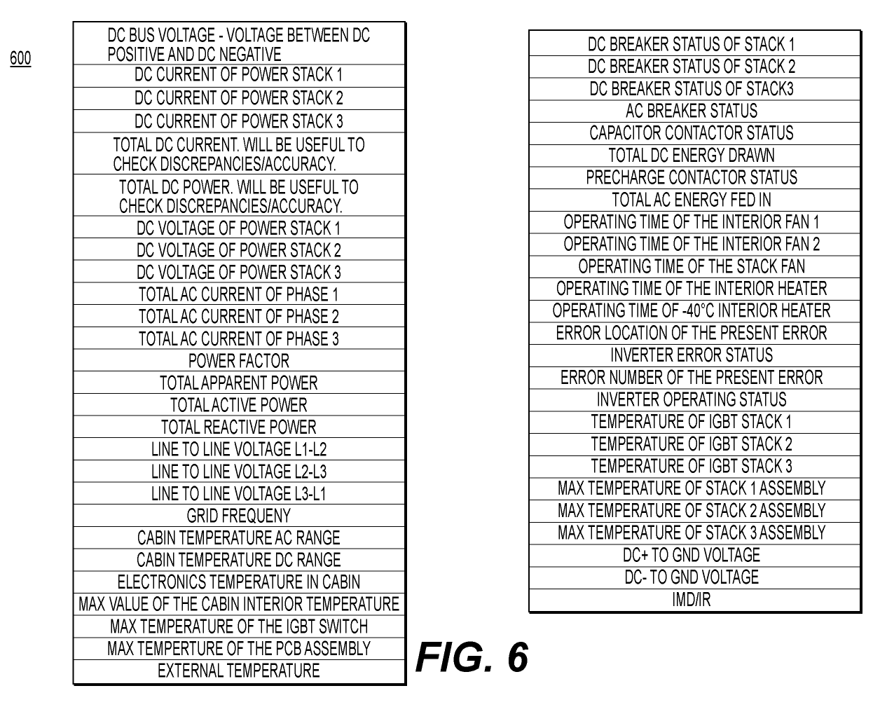

FIG. 6 depicts a table showing sample data parameters from a power conversion system, according to one or more embodiments. The table 600 illustrates a collection of data parameters that may be acquired from physical sensors within the power conversion system through Modbus protocol communication. The table 600 may list various measurement categories that may enable real-time health monitoring and predictive analytics for the inverter 520 and associated components within the system 500.

The table 600 may include DC bus voltage measurements that may provide voltage readings between DC positive and DC negative terminals of the inverter 520. These DC bus voltage measurements may serve as fundamental parameters for monitoring the electrical health and stability of the power conversion system. The table 600 may further include multi-stack current measurements including DC current of power stack 1, DC current of power stack 2, and DC current of power stack 3, which may enable individual monitoring of each power stack within the inverter 520. The table 600 may also include total DC current and total DC power measurements that may be used for verification of discrepancies and accuracy assessment across the multiple power stacks.

With continued reference to FIG. 6, the table 600 may include multi-stack voltage measurements comprising DC voltage of power stack 1, DC voltage of power stack 2, and DC voltage of power stack 3. These individual power stack voltage measurements may enable the detection of imbalances or degradation patterns within specific power conversion components. The voltage measurements in the table 600 may provide data for analyzing the performance characteristics of IGBT or MOSFET switching devices within each power stack of the inverter 520.

The table 600 may include three-phase AC measurements that may comprise total AC current of Phase 1, total AC current of Phase 2, and total AC current of Phase 3. These three-phase current measurements may enable monitoring of load balance and detection of phase-related faults within the AC output section of the inverter 520. The table 600 may further include power factor measurements, total apparent power, total active power, and total reactive power that may provide comprehensive analysis of power quality and efficiency characteristics of the power conversion system.

As further shown in FIG. 6, the table 600 may include line-to-line voltage measurements comprising line to line voltage L1-L2, line to line voltage L2-L3, and line to line voltage L3-L1, along with grid frequency measurements. These AC voltage and frequency parameters may enable monitoring of grid connection quality and detection of voltage imbalances or frequency deviations that may affect the performance of the inverter 520 and the transformer 530.

The table 600 may include multi-zone temperature monitoring parameters that may comprise cabin temperature AC range, cabin temperature DC range, electronics temperature in cabin, maximum value of the cabin interior temperature, maximum temperature of the IGBT switch, maximum temperature of the PCB assembly, and external temperature. These temperature measurements may enable comprehensive thermal monitoring across different zones and components within the inverter 520, providing data for thermal health assessment and predictive analytics algorithms.

The table 600 may include specific temperature measurements for individual power stacks comprising temperature of IGBT stack 1, temperature of IGBT stack 2, and temperature of IGBT stack 3. The table 600 may further include maximum temperature readings for stack assemblies including maximum temperature of stack 1 assembly, maximum temperature of stack 2 assembly, and maximum temperature of stack 3 assembly. These individual stack temperature measurements may enable detection of thermal imbalances and degradation patterns within specific power conversion components.

The table 600 may include breaker status tracking parameters that may comprise DC breaker status of stack 1, DC breaker status of stack 2, DC breaker status of stack 3, AC breaker status, capacitor contactor status, and precharge contactor status. These status indicators may provide real-time monitoring of protective device positions and may enable detection of operational anomalies or safety-related conditions within the inverter 520.

The table 600 may include energy and operational time parameters comprising total DC energy drawn, total AC energy fed in, operating time of interior fan 1, operating time of interior fan 2, operating time of stack fan, operating time of interior heater, and operating time of -40° C. interior heater. These operational parameters may enable monitoring of energy flow patterns and cooling system performance, providing data for efficiency analysis and predictive maintenance scheduling.

The table 600 may include error-related parameters comprising error location of the present error, inverter error status, and error number of the present error, along with inverter operating status. These error tracking parameters may enable real-time fault detection and diagnostic capabilities within the power conversion system monitoring framework.

The table 600 may include IMD/IR measurements comprising DC+ to GND voltage, DC- to GND voltage, and IMD/IR (insulation monitoring device/insulation resistance) readings. These insulation monitoring parameters may enable detection of ground faults and insulation degradation within the inverter 520, providing data for safety assessment and predictive maintenance algorithms. The IMD/IR measurements may serve as indicators for electrical isolation integrity and may contribute to the overall health assessment of the power conversion system components.

The comprehensive data parameters listed in the table 600 may be collected through Modbus protocol communication, which may enable standardized data acquisition from the physical sensors distributed throughout the inverter 520. The Modbus protocol may provide reliable communication between the controller 300 and the various sensor systems within the power conversion infrastructure, enabling real-time data collection for machine learning model processing and predictive analytics implementation.

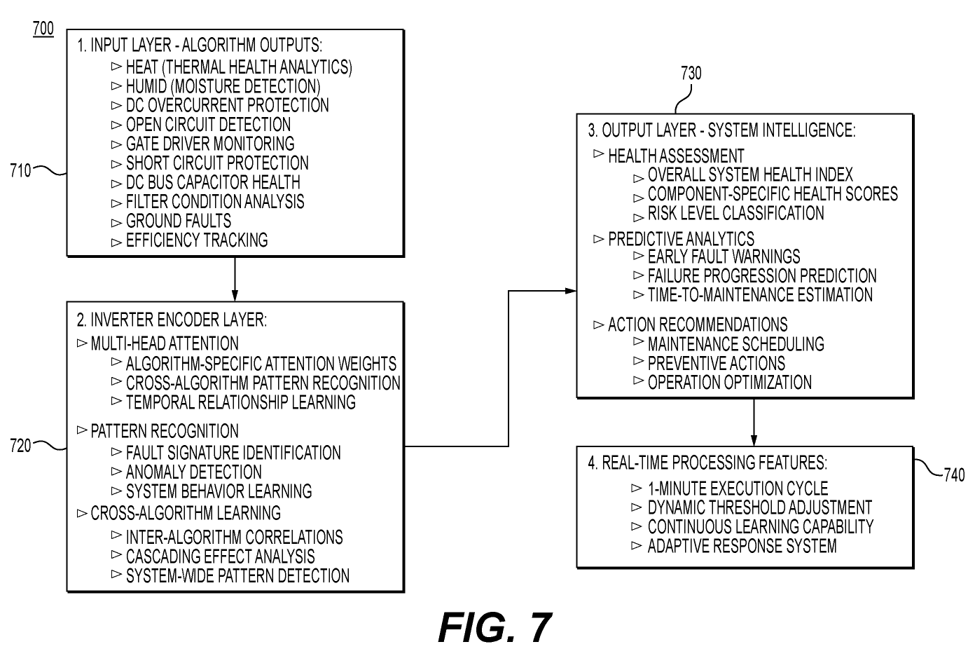

FIG. 7 depicts an exemplary flow diagram illustrating a machine learning architecture, according to one or more embodiments. A flow diagram 700 may illustrate an advanced inverter learning architecture for algorithmic system health assessment, according to one or more embodiments. The flow diagram 700 may include an input layer 710, an inverter encoder layer 720, an output layer 730, and a real-time processing 740. The flow diagram 700 may implement a dual-time-scale hybrid deep learning architecture with fast-scale processing at approximately 5 milliseconds and normal-scale processing at 1 second intervals. This architecture may provide comprehensive power electronics health monitoring through attention-based fusion mechanisms that may correlate high-frequency fault signatures with normal operational patterns.

Referring to FIG. 7, the input layer 710 may receive algorithm outputs from multiple independent monitoring algorithms that may operate simultaneously within the battery energy storage system. The input layer 710 may process outputs from the HEAT (Hierarchical Evaluation & Analysis of Thermal-patterns) algorithm that may provide thermal health analytics including multi-scale thermal response rate analysis, cross sensor correlations, temperature differentials, and statistical analysis for each sensor within the inverter 520. The input layer 710 may further receive outputs from the HUMID (Heat-based Utility for Moisture Identification and Detection) algorithm that may function as a virtual humidity sensor by analyzing temperature spread factors, convergence quality scores, component response values, and load impact assessments.

The HEAT algorithm provides comprehensive thermal monitoring for power conversion systems through multi-scale analysis of temperature data. It determines thermal response rates by monitoring delta temperature changes between case and assembly temperatures relative to switching frequency and DC current variations, including lag response analysis and power loss rate calculations.

The algorithm performs cross sensor correlation analysis through horizontal sensor-to-sensor correlations within individual components and vertical stack-to-stack correlations across different power assemblies. This enables detection of localized thermal imbalances, sensor drift conditions, and system-wide thermal distribution patterns that may indicate component degradation or cooling system inefficiencies.

Temperature differential analysis examines absolute temperature differences between case to assembly, assembly to electronics and heat exchanger, and electronics to cabin and heat exchanger. These measurements monitor thermal resistance changes, thermal transfer efficiency, and cooling system effectiveness while providing quantitative measures of thermal transfer efficiency across multiple pathways.

The HEAT algorithm may conduct trend analysis using statistical processing with rolling averages at 1-minute, 10-minute, and 1-hour intervals to capture short-term transients, medium-term patterns, and long-term thermal drift. It also tracks minimum/maximum temperatures, standard deviation values, and relative cooling rates to assess thermal stability and component response characteristics.

A thermal health index is generated by integrating thermal response rates, cross sensor correlations, temperature differentials, and trend analysis through weighted combination algorithms. This produces a unified thermal health percentage score ranging from 0% (severe degradation) to 100% (optimal performance), updated in real-time with threshold comparisons against predetermined criteria.

The HUMID algorithm functions as a virtual humidity sensor, providing moisture detection without physical humidity measurement hardware. It analyzes temperature spread factors by examining initial spread magnitude among case, PCB, and cabin temperatures, along with the rate of spread reduction during thermal equilibration processes to infer humidity conditions.

Convergence quality scoring evaluates uniformity of convergence, consistency of rates, and pattern stability across thermal transient events. Component response values monitor relative cooling rates and temperature relationships between components, while load impact analysis assesses how different loading conditions affect thermal relationships, particularly during low-load periods when humidity effects may be more apparent.

The HUMID algorithm may generate a humidity health index by integrating temperature spread factors, convergence quality scores, component response values, and load impact assessments. This produces a percentage score from 0% (potential moisture issues) to 100% (optimal humidity conditions) without requiring direct humidity measurements or ambient condition monitoring equipment.

Both algorithms provide technology improvements through early fault detection, enabling proactive component protection via automated load reduction and cooling system optimization. The HEAT algorithm enables predictive maintenance scheduling based on actual thermal degradation rates, while the HUMID algorithm offers energy-efficient operation by activating only when needed with precise risk discrimination.

The virtual humidity sensing approach eliminates the cost and complexity of physical humidity sensors while providing accurate moisture detection through existing temperature sensor infrastructure. Both algorithms operate in real-time with continuous monitoring capabilities, offering climate-independent operation and early detection of moisture-related risks during formation stages to enable proactive protection measures.

The input layer 710 may receive additional algorithm outputs including DC overcurrent protection data, open circuit detection information, gate driver monitoring parameters, short circuit protection indicators, DC bus capacitor health metrics, filter condition analysis results, ground fault detection signals, and efficiency tracking measurements. Each algorithm may operate independently and may provide specific health assessment data to the input layer 710, enabling comprehensive monitoring of power conversion system components without requiring additional specialized sensors beyond those already present in the inverter 520.

The inverter encoder layer 720 may process the algorithm outputs received from the input layer 710 through multi-head attention operations that may implement algorithm-specific attention weights for different types of health monitoring data. The inverter encoder layer 720 may perform cross-algorithm pattern recognition that may identify correlations between different monitoring parameters and may enable detection of complex failure modes that may span multiple components within the battery energy storage system. The multi-head attention mechanism may assign different attention weights to thermal data from the HEAT algorithm compared to virtual humidity data from the HUMID algorithm, enabling optimized processing of heterogeneous monitoring information.

The inverter encoder layer 720 may implement temporal relationship learning that may analyze patterns across the dual time scales of fast-scale processing at approximately 5 milliseconds and normal-scale processing at 1 second intervals. This distributed processing approach may improve computer hardware functioning by enabling parallel analysis of high-frequency switching transients and longer-term thermal drift patterns within the same computational framework. The inverter encoder layer 720 may perform fault signature identification through pattern recognition algorithms that may detect anomalies in power conversion system behavior and may implement system behavior learning that may adapt to changing operational conditions over time.

With continued reference to FIG. 7, the inverter encoder layer 720 may conduct cross-algorithm learning through inter-algorithm correlation analysis that may identify relationships between different health monitoring parameters. The inverter encoder layer 720 may perform cascading effect analysis that may predict how degradation in one component may affect the performance of other components within the battery energy storage system. For example, the inverter encoder layer 720 may correlate thermal degradation patterns detected by the HEAT algorithm with humidity-related stress indicators identified by the HUMID algorithm to predict potential insulation failures in power electronics components.

The output layer 730 may generate system intelligence based on the processed data from the inverter encoder layer 720. The output layer 730 may provide health assessment information including an overall system health index that may combine individual component health scores into a unified assessment metric. The output layer 730 may generate component-specific health scores for individual power stacks, IGBT switches, DC bus capacitors, and AC filters within the inverter 520. The output layer 730 may implement risk level classification that may categorize detected conditions into different severity levels for maintenance planning purposes.

The output layer 730 may generate predictive analytics including early fault warnings that may alert operators to potential component failures before they occur. The output layer 730 may implement failure progression prediction algorithms that may estimate the rate of component degradation and may provide time-to-maintenance estimation that may optimize maintenance scheduling to prevent unplanned outages. The predictive analytics generated by the output layer 730 may utilize thermal health index values from the HEAT algorithm and humidity health index values from the HUMID algorithm to predict specific failure modes including thermal runaway conditions, insulation breakdown, and power electronics degradation.

The output layer 730 may provide action recommendations including maintenance scheduling optimization, preventive action suggestions, and operation optimization recommendations. These action recommendations may be generated based on the correlation analysis performed by the inverter encoder layer 720 and may account for the interdependencies between different system components identified through cross-algorithm learning processes.

Real-time processing 740 may operate in conjunction with the input layer 710, the inverter encoder layer 720, and the output layer 730 to provide continuous monitoring capabilities with 1-minute execution cycles. Real-time processing 740 may implement dynamic threshold adjustment that may adapt monitoring thresholds in real-time based on changing system conditions and operational parameters. This dynamic threshold adjustment may improve computer hardware functioning by reducing false alarm rates and may optimize computational resource utilization by focusing processing power on the most relevant monitoring parameters.

Real-time processing 740 may implement continuous learning capability that may allow the machine learning model to adapt and improve performance over time during operation. The continuous learning capability may update algorithm weights and correlation parameters based on observed system behavior and may enhance the accuracy of health predictions through accumulated operational experience. Real-time processing 740 may implement an adaptive response system that may automatically adjust operational parameters of the inverter 520 based on detected health conditions, providing proactive protection against component failures.

As further shown in FIG. 7, real-time processing 740 may enable system-wide pattern detection that may identify complex failure modes spanning multiple components within the battery energy storage system. The system-wide pattern detection may correlate thermal patterns detected by the HEAT algorithm with virtual humidity measurements from the HUMID algorithm to predict moisture-related degradation in power electronics components. Real-time processing 740 may optimize controller 300 operations by implementing efficient data processing algorithms that may reduce computational overhead while maintaining comprehensive monitoring coverage.

The machine learning model comprising the inverter encoder layer 720 may be configured to perform multi-head attention, pattern recognition, and cross-algorithm learning for processing the data set in real-time with a one-minute execution cycle. This configuration may enable the method to process heterogeneous monitoring data from multiple algorithms simultaneously while maintaining real-time performance requirements for industrial battery energy storage applications. The inverter encoder layer 720 may implement algorithm-specific attention mechanisms that may optimize processing of thermal data from the HEAT algorithm and virtual humidity data from the HUMID algorithm according to their respective data characteristics and temporal patterns.

The architecture illustrated in the flow diagram 700 may provide improvements in the functioning of computer hardware through distributed processing capabilities that may enable parallel execution of multiple monitoring algorithms without requiring additional computational resources. The dynamic threshold adjustment implemented by real-time processing 740 may optimize memory 304 utilization by adapting data storage requirements based on current system conditions. The adaptive response systems may optimize processor 302 operations by implementing predictive control algorithms that may reduce computational load during normal operating conditions while maintaining enhanced monitoring during fault conditions.

One or more embodiments may implement additional predictive analytics algorithms that may operate independently while contributing to a unified system health assessment framework for comprehensive power conversion system monitoring. These additional algorithms may include DC overcurrent detection that may monitor current levels exceeding predetermined thresholds in power conversion circuits, open phase fault detection that may identify missing or interrupted phases in three-phase power systems, gate driver fault monitoring that may assess the operational status of IGBT or MOSFET gate control circuits, short circuit fault protection that may detect abnormal low-impedance conditions in power electronics components, DC bus capacitor health assessment that may evaluate capacitor degradation through impedance and ripple current analysis, AC filter condition analysis that may monitor harmonic filtering performance and component degradation, and ground fault detection that may identify insulation failures and unintended current paths to ground. These algorithms may provide improvements in technology by implementing early detection capabilities that may identify and catch risks at their formation stage, enabling proactive protection measures and enhanced fault tolerance mechanisms that may prevent system failures before component damage occurs, thereby extending equipment lifetime and reducing maintenance costs through predictive intervention strategies.

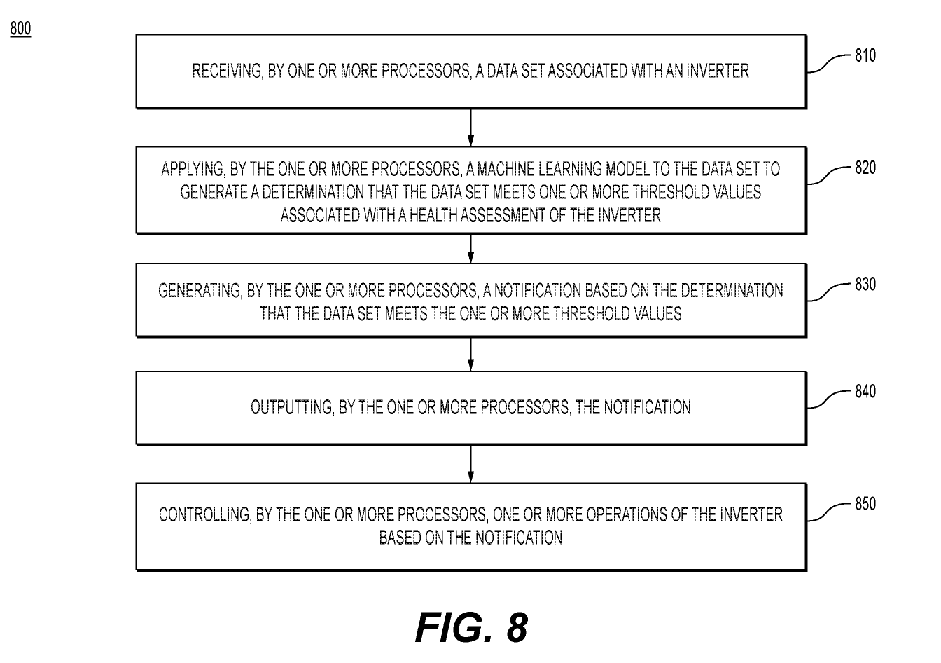

FIG. 8 depicts an exemplary flow diagram for a health monitoring and control process, according to one or more embodiments. Flow diagram 800 may illustrate a health monitoring and notification process for a power conversion system, according to one or more embodiments. The flow diagram 800 may implement a systematic approach to monitoring inverter health by processing real-time data through machine learning models, generating notifications when threshold conditions are met, and implementing control actions based on those notifications. The flow diagram 800 may provide comprehensive health assessment capabilities that may enable predictive maintenance and proactive system protection for battery energy storage applications.

The flow diagram 800 may begin with an operation 810, where one or more processors of the controller 300 may receive a data set from the inverter 520. The data set may include operational parameters collected through Modbus protocol communication from physical sensors distributed throughout the inverter 520. The data set may comprise DC bus voltage measurements, multi-stack current readings including DC current of power stack 1, DC current of power stack 2, and DC current of power stack 3, along with corresponding voltage measurements for each power stack. The data set may further include three-phase AC measurements comprising total AC current of Phase 1, total AC current of Phase 2, and total AC current of Phase 3, power factor measurements, and line-to-line voltage readings.

The operation 810 may collect comprehensive temperature monitoring data including cabin temperature measurements for AC and DC ranges, electronics temperature readings, maximum IGBT switch temperatures, and individual temperature measurements for IGBT stack 1, IGBT stack 2, and IGBT stack 3. The data collection may include status indicators for DC breaker status of each stack, AC breaker status, capacitor contactor status, and precharge contactor status. The operation 810 may further acquire energy and operational time parameters including total DC energy drawn, total AC energy fed in, and operating times for various cooling system components including interior fans, stack fans, and heating elements.

The data set received in the operation 810 may include error-related parameters comprising error location information, inverter error status, and error number identification, along with inverter operating status indicators. The operation 810 may collect insulation monitoring parameters including DC+ to GND voltage, DC- to GND voltage, and IMD/IR measurements that may provide insulation resistance data for ground fault detection and electrical isolation assessment. The comprehensive data collection implemented in the operation 810 may enable real-time monitoring of power conversion system components without requiring additional specialized sensors beyond those already present in the inverter 520.

The flow diagram 800 may proceed to an operation 820, where the one or more processors may apply the machine learning model to the data set to generate a determination that the data set meets one or more threshold values associated with a health assessment of the inverter 520. The operation 820 may implement the dual-time-scale hybrid deep learning architecture with fast-scale processing at approximately 5 milliseconds and normal-scale processing at approximately 1 second intervals. The machine learning model may process the data set through the input layer 710, the inverter encoder layer 720, and the output layer 730 to generate comprehensive health assessment determinations.

The operation 820 may apply the HEAT algorithm to analyze thermal data within the data set, determining thermal response rates through multi-scale thermal response rate analysis that may monitor delta temperature changes between case temperature and assembly temperature relative to switching frequency and DC current changes. The operation 820 may determine cross sensor correlations through horizontal sensor-to-sensor analysis and vertical stack-to-stack analysis, enabling detection of thermal imbalances and sensor drift conditions. The operation 820 may calculate temperature differentials including case to assembly, assembly to electronics and heat exchanger, and electronics to cabin and heat exchanger measurements.

The operation 820 may implement the HUMID algorithm to analyze temperature-based parameters for virtual humidity sensing, determining temperature spread factors through analysis of initial spread magnitude among case temperature, PCB temperature, and cabin temperature. The operation 820 may calculate convergence quality scores based on uniformity of convergence, consistency of rates, and pattern stability assessments. The operation 820 may determine component response values through monitoring of relative cooling rates and component temperature relationships, and may assess load impact through evaluation of duration of low load conditions and load stability measurements.

The operation 820 may generate a thermal health index based on the thermal response rate, cross sensor correlations, temperature differentials, and trend analysis associated with the inverter 520. The operation 820 may generate a humidity health index based on the temperature spread factor, convergence quality score, component response values, and load impact associated with the inverter 520. The one or more threshold values may be determined based on one or more of the thermal health index or the humidity health index associated with the inverter 520, enabling comprehensive health assessment that may account for both thermal and moisture-related degradation patterns.

The machine learning model may implement dynamic threshold adjustment capabilities that may adapt the one or more threshold values in real-time based on changing system conditions and operational parameters. The dynamic threshold adjustment may monitor operational loading patterns, ambient temperature variations, and seasonal environmental changes to optimize threshold values for different operating conditions. The adaptive threshold mechanisms may reduce false alarm rates by accounting for normal operational variations while maintaining sensitivity to actual degradation patterns that may indicate component health issues.

The operation 820 may implement additional predictive analytics algorithms including DC overcurrent detection, open phase fault monitoring, gate driver fault assessment, short circuit fault protection, DC bus capacitor health evaluation, AC filter condition analysis, and ground fault detection. Each algorithm may operate independently while contributing to the unified health assessment determination, enabling comprehensive monitoring of power conversion system components through correlation analysis and cascading effect evaluation.

The flow diagram 800 may continue to an operation 830, where the one or more processors may generate a notification based on the determination that the data set meets the one or more threshold values. The operation 830 may create notifications that may include specific health assessment information, component identification, severity level classification, and recommended actions based on the health assessment results generated in the operation 820. The notification generation may correlate thermal health index values with humidity health index values to provide comprehensive assessment information that may account for multiple degradation mechanisms affecting the inverter 520.

The operation 830 may generate notifications that may include early fault warnings when thermal health index values fall below predetermined thermal performance thresholds or when humidity health index values indicate potential moisture-related issues. The notification generation may implement failure progression prediction that may estimate the rate of component degradation and may provide time-to-maintenance estimation based on current degradation trends identified through the machine learning model analysis. The operation 830 may generate component-specific notifications for individual power stacks, IGBT switches, DC bus capacitors, and AC filters within the inverter 520.

The operation 830 may create notifications that may include risk level classification information, categorizing detected conditions into different severity levels including normal operation, caution levels requiring monitoring, warning levels requiring attention, and critical levels requiring immediate action. The notification generation may provide predictive analytics information including projected failure timelines, recommended maintenance windows, and operational parameter adjustments that may prevent component failures.

The flow diagram 800 may proceed to an operation 840, where the one or more processors may output the notification generated in the operation 830. The operation 840 may transmit notifications through the communication port or interface 320 to external monitoring systems, maintenance management platforms, or operator interfaces. The notification output may utilize the network 370 to communicate with power plant controllers, utility energy management systems, or fleet-level control systems that may coordinate maintenance activities across multiple battery energy storage installations.

The operation 840 may display notification information on the display 310 of the controller 300, providing visual alerts and health assessment summaries to local operators. The notification output may include graphical representations of thermal health index trends, humidity health index values, and component-specific health scores that may enable rapid assessment of system conditions. The operation 840 may implement notification prioritization that may ensure critical alerts receive immediate attention while routine health status updates are provided through standard reporting channels.

The operation 840 may generate notification logs that may be stored in the memory 304 for historical analysis and trend tracking purposes. The notification output may include timestamp information, health assessment values, and recommended actions that may support maintenance planning and system performance analysis. The operation 840 may implement notification filtering that may reduce information overload by grouping related alerts and providing summary information for multiple component health assessments.

The flow diagram 800 may conclude with an operation 850, where the one or more processors may control one or more operations of the inverter 520 based on the notification generated in the operation 830. The operation 850 may implement adaptive control actions that may automatically adjust operational parameters of the inverter 520 based on detected health conditions, providing proactive protection against component failures. The control operations may include load reduction algorithms that may decrease power conversion system loading when thermal stress conditions are detected through thermal health index monitoring.

The one or more operations of the inverter 520 may include scheduling a maintenance request when health assessment values indicate component degradation requiring preventive maintenance intervention. The operation 850 may automatically generate maintenance work orders and may coordinate maintenance scheduling with external maintenance management systems through the communication port or interface 320. The maintenance scheduling may optimize maintenance intervals based on actual component degradation rates identified through the machine learning model analysis rather than fixed time schedules.

The one or more operations of the inverter 520 may include preventing one or more actions associated with the inverter 520 when health assessment determinations indicate potential safety risks or component damage conditions. The operation 850 may implement protective control actions including disabling specific power stacks when thermal health index values indicate overheating conditions, preventing high-current operations when DC bus capacitor health assessments indicate degradation, or restricting switching frequencies when gate driver fault monitoring detects control circuit issues.

The one or more operations of the inverter 520 may include optimizing one or more operations of the inverter 520 based on health assessment information to maximize system performance while preventing component degradation. The operation 850 may implement cooling system optimization that may increase fan speeds or adjust coolant flow rates when thermal health degradation is identified through the HEAT algorithm analysis. The operational optimization may include power factor correction adjustments, harmonic filtering optimization, and switching frequency modifications that may reduce component stress while maintaining power conversion efficiency.

The operation 850 may implement adaptive response systems that may provide smooth transitions between operating states based on health assessment conditions. The adaptive control mechanisms may gradually adjust operational parameters to prevent sudden changes that may cause additional component stress while transitioning to protective operating modes. The operation 850 may implement predictive control algorithms that may anticipate component degradation trends and may proactively adjust operational parameters before threshold conditions are reached.

The health monitoring and notification process illustrated in the flow diagram 800 may provide improvements in the functioning of hardware performance by implementing real-time monitoring with dynamic threshold adjustment capabilities. The real-time processing may operate with approximately 1-minute execution cycles that may enable continuous monitoring of power conversion system components while optimizing computational resource utilization through efficient data processing algorithms. The dynamic threshold adjustment may improve processor 302 performance by reducing computational overhead during normal operating conditions while maintaining enhanced monitoring sensitivity during fault conditions.

The real-time monitoring implementation may optimize memory 304 utilization by adapting data storage requirements based on current system conditions and health assessment results. The dynamic threshold adjustment may reduce false alarm processing by automatically calibrating threshold values based on operational patterns and environmental conditions, thereby reducing unnecessary computational load on the processor 302. The real-time processing capabilities may enable immediate detection of component degradation patterns and may implement rapid response mechanisms that may prevent system failures before component damage occurs.

The adaptive control actions implemented in the operation 850 may provide improvements in hardware performance by optimizing power conversion system efficiency through intelligent control algorithms that may reduce parasitic losses and component stress. The adaptive response systems may implement predictive control mechanisms that may anticipate system behavior changes and may proactively adjust operational parameters to maintain optimal performance while preventing component degradation. The adaptive control implementation may reduce energy consumption by optimizing cooling system operation through predictive thermal management that may activate cooling resources only when needed rather than continuously.

The adaptive control actions may improve the functioning of the inverter 520 hardware by implementing load balancing algorithms that may distribute electrical and thermal stress evenly across multiple power stacks, thereby extending component lifetime and improving system reliability. The control optimization may reduce mechanical stress on cooling system components by implementing intelligent fan control algorithms that may reduce unnecessary cooling system operation while maintaining adequate thermal protection. The adaptive response mechanisms may enable the inverter 520 to operate closer to rated capacity by providing continuous health monitoring that may ensure safe operation within design limits while maximizing power conversion capability.

The health monitoring and notification process may provide technology improvements by enabling early fault detection capabilities that may identify component degradation patterns before failures occur, thereby reducing unplanned system downtime and maintenance costs. The predictive health assessment may enable proactive maintenance scheduling that may optimize maintenance intervals based on actual component condition rather than fixed time schedules, improving system availability while reducing maintenance expenses. The comprehensive health monitoring framework may extend equipment lifetime by implementing protective control actions that may prevent component damage during fault conditions while maintaining system operational capability.

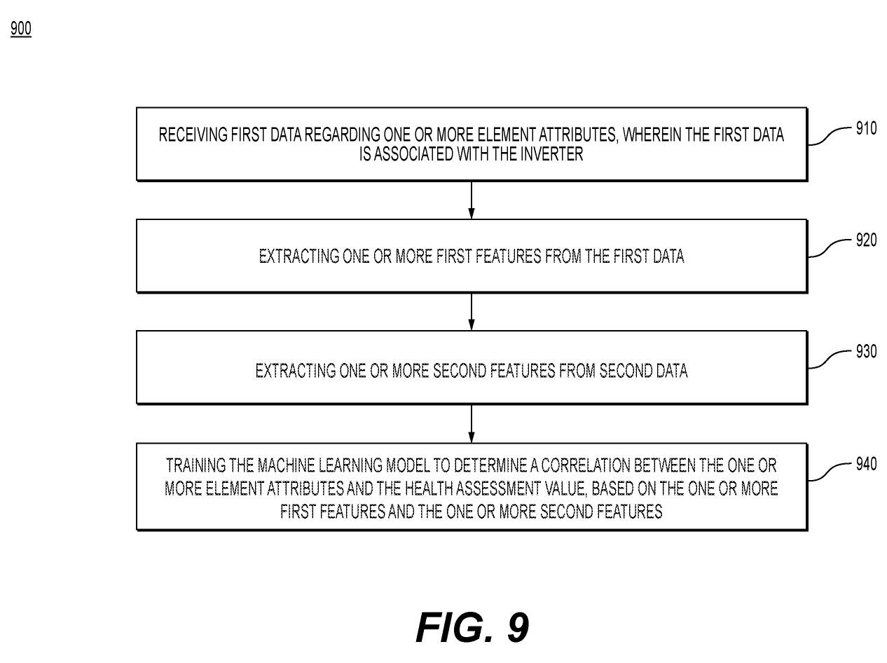

FIG. 9 depicts an exemplary flow diagram for training the machine learning model of FIG. 8, according to one or more embodiments. A flow diagram 900 may establish correlations between inverter component attributes and health assessment parameters through systematic feature extraction and model development. The flow diagram 900 may illustrate the sequential training methodology that may enable the machine learning model to learn complex relationships between operational data patterns and component health indicators. The flow diagram 900 may begin with an operation 910, where first data regarding one or more element attributes associated with the inverter 520 may be received by the one or more processors of the controller 300. The first data may comprise historical operational parameters including temperature measurements, current readings, voltage levels, and component status indicators that may represent known operational conditions of the inverter 520 components.

The flow diagram 900 may proceed to an operation 920, where one or more first features may be extracted from the first data through analytical processing algorithms that may identify relevant patterns and characteristics within the historical operational data. The first feature extraction may include thermal response patterns, electrical parameter variations, and component behavior signatures that may correlate with specific health conditions of power conversion system components. The operation 920 may implement feature engineering techniques that may transform raw operational data into meaningful analytical parameters suitable for machine learning model training.

The one or more first features extracted in the operation 920 may include specific thermal characteristics such as temperature rise rates, thermal cycling patterns, heat dissipation efficiency measurements, and thermal coupling coefficients between adjacent components. The first features may further encompass electrical parameter variations including voltage ripple patterns, current harmonic content, power factor fluctuations, switching frequency deviations, and impedance changes that may indicate component degradation. The component behavior signatures within the first features may comprise IGBT switching characteristics, capacitor equivalent series resistance trends, filter performance metrics, and insulation resistance degradation patterns that may provide early indicators of component health deterioration.

The flow diagram 900 may continue to an operation 930, where one or more second features may be extracted from second data that may provide additional contextual information for training the machine learning model. The second data may comprise environmental conditions, operational loading patterns, maintenance history records, and component failure information that may enhance the training dataset with comprehensive operational context. The second feature extraction may identify temporal patterns, seasonal variations, and operational dependencies that may influence component health assessment accuracy.

The one or more second features extracted in the operation 930 may include environmental condition parameters such as ambient temperature variations, humidity levels, atmospheric pressure changes, and seasonal climate patterns that may affect component performance and degradation rates. The operational loading patterns within the second features may comprise power demand cycles, load factor variations, peak demand frequency, charging and discharging patterns, and grid frequency stability measurements. The maintenance history records may include previous component replacements, repair activities, performance test results, and preventive maintenance intervals that may provide historical context for component health assessment. The component failure information may encompass failure mode classifications, root cause analysis data, time-to-failure statistics, and cascading failure patterns that may enhance the machine learning model's ability to predict similar failure conditions in operational systems.

The flow diagram 900 may conclude with an operation 940, where the machine learning model may be trained to determine correlations between the one or more element attributes and health assessment values based on the one or more first features and the one or more second features. The training process may implement supervised learning algorithms that may establish predictive relationships between extracted features and known component health outcomes, enabling the trained machine learning model 440 to generate accurate health assessments for new operational data inputs.

Following the operation 940, the flow diagram 900 may validate the trained machine learning model. The validation of the trained machine learning model may be essential to ensure accurate health predictions for operational inverter systems, particularly given that most existing research solutions are lab-only prototypes that typically cannot handle the limited real-world data available in field deployments. One or more embodiments may implement validation procedures that test the machine learning model against real-world operational conditions and variations to ensure the model may handle the practical challenges of field-deployable BESS applications. The validation data may include diverse operational scenarios, environmental conditions, and component degradation patterns that represent the full spectrum of conditions the inverter may encounter during actual operation, thereby ensuring the trained model can accurately predict thermal health indices, humidity health indices, and component-specific health scores across varying operational parameters.

The validation process may further ensure that the machine learning model maintains accuracy across the dual-time-scale hybrid deep learning architecture, validating both fast-scale processing and normal-scale processing. One or more embodiments may implement validation methodologies that verify the model's ability to correlate high-frequency fault signatures with normal operational patterns, ensuring that the attention-based fusion mechanisms accurately identify degradation patterns in power stacks, IGBTs, MOSFETs, DC bus capacitors, and AC filters. The validation may include testing the model's performance against known failure progression patterns and component degradation scenarios to confirm that the predictive analytics capabilities, including early fault warnings, failure progression prediction, and time-to-maintenance estimation, provide reliable and actionable health assessments for maintenance scheduling and operational optimization in real-world BESS installations.

This training process may provide improvements in technology by enhancing prediction accuracy through sophisticated correlation analysis that may identify complex interdependencies between multiple operational parameters and component degradation patterns. The temporal tracking capabilities developed through the training process may enable the machine learning model to recognize long-term degradation trends and seasonal operational variations that may affect component health assessment reliability. The correlation analysis implemented during training may establish predictive relationships that may account for cascading effects between different system components, enabling more comprehensive health assessment capabilities that may predict system-wide performance impacts from individual component degradation patterns.

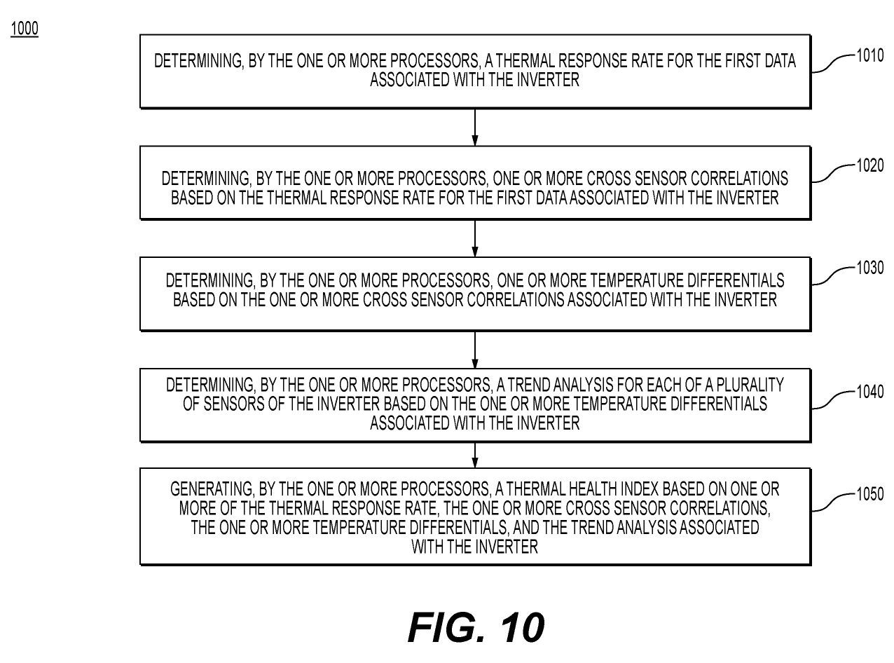

FIG. 10 depicts an exemplary flow diagram for determining a thermal health index, according to one or more embodiments. A flow diagram 1000 illustrates a thermal health index determination process that may implement systematic thermal monitoring through sequential analytical operations. The flow diagram 1000 may begin with an operation 1010, where the one or more processors may determine a thermal response rate for first data associated with the inverter 520 through multi-scale thermal response rate analysis that may include lag response analysis and power loss rate calculations expressed as d(power loss)/dt. The lag response analysis may track time delays between thermal input changes and corresponding temperature responses across different system components, while the power loss rate calculations may quantify the rate of energy dissipation changes within power electronics components.

The flow diagram 1000 may proceed to an operation 1020, where the one or more processors may determine one or more cross sensor correlations based on the thermal response rate for the first data associated with the inverter 520 through horizontal sensor-to-sensor analysis and vertical stack-to-stack analysis that may identify thermal relationships between sensors positioned at similar hierarchical levels and across different power stack assemblies. An operation 1030 may follow, where the one or more processors may determine one or more temperature differentials based on the one or more cross sensor correlations associated with the inverter 520 through analysis of absolute temperature differentials between case to assembly, assembly to electronics and heat exchanger, and electronics to cabin and heat exchanger that may provide quantitative measures of thermal transfer efficiency across multiple thermal pathways.

The flow diagram 1000 may continue to an operation 1040, where the one or more processors may determine a trend analysis for each of a plurality of sensors of the inverter 520 based on the one or more temperature differentials associated with the inverter 520 through statistical processing that may calculate rolling averages for multiple time windows including 1 minute intervals for short-term thermal trend identification, 10 minute intervals for medium-term thermal patterns, and 1 hour intervals for long-term thermal drift patterns. An operation 1050 may conclude the flow diagram 1000, where the one or more processors may generate a thermal health index based on one or more of the thermal response rate, the one or more cross sensor correlations, the one or more temperature differentials, and the trend analysis associated with the inverter 520 through weighted combination algorithms that may produce a unified thermal health percentage score.

This systematic thermal monitoring process may provide improvements in technology by reducing thermal stress on power electronics components through early detection of thermal degradation patterns that may enable proactive component protection before temperature limits are exceeded, and by enabling predictive thermal management through advanced analytics that may optimize cooling system operation and prevent component failures through intelligent thermal control algorithms that may activate protective measures based on thermal health assessment results.

One or more embodiments may implement a predictive maintenance scheduling methodology that may collect performance degradation data from multiple components of a battery energy storage system including power conversion systems and transformers. The performance degradation data collection may encompass thermal degradation patterns from power electronics components, insulation resistance measurements from transformers, capacitor equivalent series resistance trends, filter performance metrics, and switching device characteristic changes that may indicate component aging or stress accumulation. The data collection process may monitor component stress factors including thermal cycling frequency, electrical loading patterns, voltage stress levels, current density variations, and mechanical vibration exposure that may contribute to component degradation over time.

The predictive maintenance scheduling methodology may apply a machine learning algorithm to identify failure progression patterns in the performance degradation data through temporal analysis that may recognize characteristic degradation signatures associated with specific failure modes. The machine learning algorithm may analyze operational history data including component usage patterns, maintenance intervals, environmental exposure conditions, and previous failure events to establish predictive models that may correlate current component conditions with historical failure progression patterns. The failure progression pattern identification may enable early detection of degradation trends that may precede component failures, allowing maintenance interventions to be scheduled before critical failure conditions are reached.

The methodology may calculate remaining useful life estimates for each of the multiple components based on the failure progression patterns through comprehensive analysis of component stress factors, operational history, and environmental conditions to predict time-to-failure with confidence intervals. The remaining useful life calculations may incorporate stress factor analysis including thermal stress accumulation, electrical stress exposure, mechanical stress cycles, and chemical degradation processes that may affect component longevity. The operational history analysis may evaluate component usage patterns, load factor variations, operational temperature ranges, and maintenance history to establish baseline degradation rates for individual components.

The environmental conditions analysis may account for ambient temperature variations, humidity exposure, atmospheric contamination levels, and seasonal climate patterns that may influence component degradation rates and failure progression timelines. The time-to-failure prediction may utilize statistical modeling techniques that may generate confidence intervals representing the probability distribution of potential failure times, enabling maintenance planning that may account for uncertainty in degradation progression rates. The confidence interval calculations may provide risk assessment information that may support maintenance decision-making by quantifying the likelihood of component failure within specific time periods.

The predictive maintenance scheduling methodology may optimize maintenance schedules to reduce system downtime while preventing component failures through coordinated scheduling algorithms that may balance maintenance resource allocation with operational availability requirements. The maintenance schedule optimization may coordinate maintenance windows across multiple battery energy storage systems to maintain grid stability and energy supply continuity by ensuring that maintenance activities do not simultaneously affect multiple systems serving the same electrical grid region. The coordinated scheduling may account for grid demand patterns, renewable energy generation forecasts, and backup power availability to reduce the impact of maintenance activities on electrical grid stability.

The methodology may automatically schedule maintenance activities based on the optimized maintenance schedules through integration with maintenance management systems that may generate work orders, allocate maintenance resources, and coordinate technician scheduling based on predicted component failure timelines. The automatic scheduling may implement priority-based maintenance allocation that may ensure components with shorter remaining useful life estimates receive maintenance attention before components with longer predicted lifetimes. The automated maintenance scheduling may provide real-time updates to maintenance plans based on changing component conditions and may adjust maintenance priorities when accelerated degradation patterns are detected through continuous monitoring.

This predictive maintenance scheduling approach may provide improvements in technology by extending component lifetime and reliability through proactive maintenance scheduling that may prevent component failures before damage occurs, thereby reducing the frequency of emergency repairs and unplanned system outages. The proactive maintenance approach may implement preventive actions that may reduce degradation rates by addressing component stress factors before they reach levels that may cause permanent damage or performance reduction. The preventive maintenance interventions may include component cleaning, lubrication, calibration, and replacement of consumable elements that may restore component performance and may extend operational lifetime beyond standard design expectations.

The predictive maintenance methodology may provide technology improvements by enabling maintenance resource optimization that may reduce overall maintenance costs while improving system reliability through targeted maintenance interventions based on actual component condition rather than fixed time schedules. The condition-based maintenance approach may eliminate unnecessary maintenance activities on components that remain in good condition while ensuring that degraded components receive timely attention before failure occurs. The optimized maintenance scheduling may reduce system downtime by coordinating maintenance activities during planned outage windows and may reduce the duration of maintenance interventions through improved preparation and resource allocation based on predicted maintenance requirements.

The disclosed energy storage systems and methods may provide significant advantages over conventional battery energy storage monitoring approaches by implementing a dual-time-scale hybrid deep learning architecture that enables comprehensive predictive health assessment without requiring additional specialized sensors. The HEAT and HUMID algorithms deliver real-time thermal and virtual humidity monitoring capabilities through existing temperature sensors, eliminating the need for costly humidity measurement equipment while maintaining accurate moisture detection. This approach reduces implementation costs and complexity while providing early fault detection capabilities that may identify component degradation patterns before failures occur, thereby preventing unplanned system downtime and reducing emergency repair expenses.

The predictive maintenance scheduling methodology offers substantial operational benefits by optimizing maintenance intervals based on actual component condition rather than fixed time schedules, which may extend equipment lifetime and improve system reliability. The machine learning-based health monitoring framework enables proactive component protection through intelligent control algorithms that automatically adjust operational parameters when degradation is detected, allowing battery energy storage systems to operate closer to rated capacity while maintaining safety margins. This comprehensive monitoring approach provides energy efficiency improvements by activating protective measures only when needed, reduces maintenance resource requirements through targeted interventions, and enhances grid stability by coordinating maintenance activities across multiple installations to ensure continuous energy supply availability.

It should be understood that the foregoing description is intended to illustrate, and not to limit, the scope of the present disclosure. Other embodiments will be apparent to those skilled in the art in view of this description. For example, while certain embodiments are described with respect to lithium-ion batteries, the disclosed structures, materials, and methods may be applied to next-generation energy storage devices including, without limitation, solid-state batteries employing solid electrolytes, lithium-metal or lithium-sulfur chemistries, sodium-ion systems, multivalent-ion systems (e.g., magnesium, calcium, aluminum), zinc-based or redox flow batteries, and metal-air cells. Still further embodiments may include architectures employing silicon-based anodes, cobalt-free cathodes, or advanced electrolyte formulations. In some cases, anode-less designs, in which active material is plated during charge, or separator-free designs, in which the electrolyte provides ionic conduction and electronic insulation without a discrete separator, may be implemented. The present disclosure also contemplates hybridized devices combining electrochemical cells with supercapacitors, as well as integration into applications such as electric or hybrid vehicles, stationary energy storage systems, aerospace platforms, and portable electronics. Accordingly, the scope of the present invention should be determined not by the particular embodiments described, but by reference to the appended claims and their equivalents.

The present disclosure further relates to the following aspects.

Example 1. A method comprising: receiving, by one or more processors, a data set associated with an inverter of a battery energy storage system; determining one or more threshold values based on one or more of a thermal health index or a humidity health index associated with the inverter; applying, by the one or more processors, a machine learning model to the data set to generate a determination that the data set meets the one or more threshold values associated with a health assessment of the inverter, wherein the machine learning model includes an inverter encoder layer configured to perform multi-head attention, pattern recognition, and cross-algorithm learning for processing the data set in real-time; and controlling, by the one or more processors, one or more operations of the inverter based on the determination that the data set meets the one or more threshold values associated with the health assessment of the inverter.

Example 2. The method of example 1, wherein the machine learning model is trained by: receiving first data regarding one or more element attributes, wherein the first data is associated with the inverter; extracting one or more first features from the first data; extracting one or more second features from second data; and training the machine learning model to determine a correlation between the one or more element attributes and the health assessment, based on the one or more first features, and the one or more second features.

Example 3. The method of example 2, wherein the one or more first features includes one or more of a DC overcurrent, an open phase fault, a gate driver fault, a short circuit fault, a DC bus capacitor health value, a filter condition, or one or more ground faults.

Example 4. The method of example 2, wherein extracting the one or more first features includes: determining, by the one or more processors, a thermal response rate for the first data associated with the inverter; determining, by the one or more processors, one or more cross sensor correlations based on the thermal response rate for the first data associated with the inverter; determining, by the one or more processors, one or more temperature differentials based on the one or more cross sensor correlations associated with the inverter; determining, by the one or more processors, a trend analysis for each of a plurality of sensors of the inverter based on the one or more temperature differentials associated with the inverter; and generating, by the one or more processors, the thermal health index based on one or more of the thermal response rate, the one or more cross sensor correlations, the one or more temperature differentials, or the trend analysis.

Example 5. The method of example 4, wherein determining the thermal response rate includes analyzing a multi-scale thermal response rate including delta temperature changes between case temperature and assembly temperature relative to switching frequency and DC current changes.

Example 6. The method of example 4, wherein determining the one or more cross sensor correlations includes analyzing horizontal sensor-to-sensor correlations and vertical stack-to-stack correlations.

Example 7. The method of example 4, wherein determining the one or more temperature differentials includes analyzing absolute temperature differentials between case to assembly, assembly to electronics and heat exchanger, and electronics to cabin and heat exchanger.

Example 8. The method of example 2, wherein extracting the one or more first features includes: determining, by the one or more processors, a temperature spread factor for the first data associated with the inverter; determining, by the one or more processors, a convergence quality score based on the temperature spread factor associated with the inverter; determining, by the one or more processors, one or more component response values based on the convergence quality score associated with the inverter; determining, by the one or more processors, a load impact for the inverter based on the one or more component response values associated with the inverter; and generating, by the one or more processors, the humidity health index based on one or more of the temperature spread factor, the convergence quality score, the one or more component response values, and the load impact associated with the inverter.

Example 9. The method of example 8, wherein generating the humidity health index does not include measuring one or more of a humidity value or one or more ambient conditions associated with one or more components of the inverter.

Example 10. The method of example 8, wherein determining the temperature spread factor includes analyzing an initial spread magnitude among case temperature, PCB temperature, and cabin temperature, and a rate of spread reduction.

Example 11. The method of example 8, wherein determining the convergence quality score includes analyzing uniformity of convergence, consistency of rates, and pattern stability.

Example 12. The method of example 1, further comprising: generating, by the one or more processors, a notification based on the determination that the data set meets the one or more threshold values; and outputting, by the one or more processors, the notification.

Example 13. The method of example 1, wherein the one or more operations of the inverter include one or more of outputting a notification, scheduling a maintenance request, preventing one or more actions associated with the inverter, or optimizing the one or more operations of the inverter.

Example 14. The method of example 1, wherein determining the one or more threshold values further includes determining the one or more threshold values based on one or more component-specific health scores.

Example 15. A method for thermal health monitoring of an inverter in a battery energy storage system, the method comprising: determining, by one or more processors, a thermal response rate for operational data associated with the inverter using a multi-scale thermal response rate analysis; determining, by the one or more processors, one or more cross sensor correlations based on the thermal response rate using horizontal sensor-to-sensor analysis and vertical stack-to-stack analysis; determining, by the one or more processors, one or more temperature differentials based on the one or more cross sensor correlations; determining, by the one or more processors, a trend analysis for each of a plurality of sensors of the inverter based on the one or more temperature differentials; and generating, by the one or more processors, a thermal health index based on one or more of the thermal response rate, the one or more cross sensor correlations, the one or more temperature differentials, or the trend analysis associated with the inverter.

Example 16. The method of example 15, wherein the multi-scale thermal response rate analysis includes determining a delta temperature change between a case temperature and an assembly temperature relative to a switching frequency and a DC current change based on the operational data.

Example 17. The method of example 15, wherein determining the one or more temperature differentials includes determining one or more absolute temperature differentials between a case and an assembly, the assembly to a plurality of electronics and a heat exchanger, and the plurality of electronics to a cabin and the heat exchanger.

Example 18. A method for training a machine learning model to predict a health of an inverter in a battery energy storage system, the method comprising: receiving, by one or more processors, first data regarding one or more element attributes associated with the inverter, wherein the first data includes a plurality of operational parameters; extracting, by the one or more processors, one or more first features from the first data based on analyzing processing algorithms identifying at least one of a thermal response pattern, an electrical parameter variation, or a component behavior signature; extracting, by the one or more processors, one or more second features from second data, wherein the second data includes one or more of an environmental condition, an operational loading pattern, a maintenance history record, or a component failure; training, by the one or more processors, the machine learning model to determine correlations between the one or more element attributes and one or more health assessment values based on the one or more first features and the one or more second features; and validating, by the one or more processors, the trained machine learning model using validation data to ensure accurate health predictions for operational inverter systems.

Example 19. The method of example 18, wherein the plurality of operational parameters include one or more of a plurality of DC bus voltage measurements, a plurality of multi-stack current readings, a plurality of three-phase AC measurements, a plurality of temperature monitoring data, or a plurality of component status indicators.

Example 20. The method of example 18, wherein the one or more health assessment values include one or more of a thermal health index, a humidity health index, or one or more component-specific health scores.

Example 21. A system for controlling one or more operations of an inverter, the system comprising: one or more processors; and one or more memories storing instructions that, when executed by the one or more processors, cause the one or more processors to perform operations including: receive a data set associated with an inverter of a battery energy storage system; determine one or more threshold values based on one or more of a thermal health index or a humidity health index associated with the inverter; apply a machine learning model to the data set to generate a determination that the data set meets the one or more threshold values associated with a health assessment of the inverter, wherein the machine learning model includes an inverter encoder layer configured to perform multi-head attention, pattern recognition, and cross-algorithm learning for processing the data set in real-time; and control one or more operations of the inverter based on the determination that the data set meets the one or more threshold values associated with the health assessment of the inverter.

Example 22. The system of example 21, wherein the operations further include any of examples 2 to 14.

Example 23. A system for thermal health monitoring of an inverter in a battery energy storage system, the system comprising: one or more processors; and one or more memories storing instructions that, when executed by the one or more processors, cause the one or more processors to perform operations including: determine a thermal response rate for operational data associated with the inverter using a multi-scale thermal response rate analysis; determine one or more cross sensor correlations based on the thermal response rate using horizontal sensor-to-sensor analysis and vertical stack-to-stack analysis; determine one or more temperature differentials based on the one or more cross sensor correlations; determine a trend analysis for each of a plurality of sensors of the inverter based on the one or more temperature differentials; and generate a thermal health index based on one or more of the thermal response rate, the one or more cross sensor correlations, the one or more temperature differentials, or the trend analysis associated with the inverter.

Example 24. The system of example 23, wherein the operations further include any of examples 16 to 17.

Example 25. A system for training a machine learning model to predict a health of an inverter in a battery energy storage system, the system comprising: one or more processors; and one or more memories storing instructions that, when executed by the one or more processors, cause the one or more processors to perform operations including: receive first data regarding one or more element attributes associated with the inverter, wherein the first data includes a plurality of operational parameters; extract one or more first features from the first data based on analyzing processing algorithms identifying at least one of a thermal response pattern, an electrical parameter variation, or a component behavior signature; extract one or more second features from second data, wherein the second data includes one or more of an environmental condition, an operational loading pattern, a maintenance history record, or a component failure; train the machine learning model to determine correlations between the one or more element attributes and one or more health assessment values based on the one or more first features and the one or more second features; and validate the trained machine learning model using validation data to ensure accurate health predictions for operational inverter systems.

Example 26. The system of example 25, wherein the operations further include any of examples 19 to 20.

Example 27. A non-transitory computer-readable medium for controlling one or more operations of an inverter, storing instructions that, when executed by one or more processors, cause the one or more processors to: receive a data set associated with an inverter of a battery energy storage system; determine one or more threshold values based on one or more of a thermal health index or a humidity health index associated with the inverter; apply a machine learning model to the data set to generate a determination that the data set meets the one or more threshold values associated with a health assessment of the inverter, wherein the machine learning model includes an inverter encoder layer configured to perform multi-head attention, pattern recognition, and cross-algorithm learning for processing the data set in real-time; and control one or more operations of the inverter based on the determination that the data set meets the one or more threshold values associated with the health assessment of the inverter.

Example 28. The non-transitory computer readable medium of example 27, wherein the operations further include any of examples 2 to 14.

Example 29. A non-transitory computer readable medium for thermal health monitoring of an inverter in a battery energy storage system, storing instructions that, when executed by one or more processors, cause the one or more processors to: determine a thermal response rate for operational data associated with the inverter using a multi-scale thermal response rate analysis; determine one or more cross sensor correlations based on the thermal response rate using horizontal sensor-to-sensor analysis and vertical stack-to-stack analysis; determine one or more temperature differentials based on the one or more cross sensor correlations; determine a trend analysis for each of a plurality of sensors of the inverter based on the one or more temperature differentials; and generate a thermal health index based on one or more of the thermal response rate, the one or more cross sensor correlations, the one or more temperature differentials, or the trend analysis associated with the inverter.

Example 30. The non-transitory computer readable medium of example 29, wherein the operations further include any of examples 16 to 17.

Example 31. A non-transitory computer readable medium for training a machine learning model to predict a health of an inverter in a battery energy storage system, storing instructions that, when executed by one or more processors, cause the one or more processors to: receive first data regarding one or more element attributes associated with the inverter, wherein the first data includes a plurality of operational parameters; extract one or more first features from the first data based on analyzing processing algorithms identifying at least one of a thermal response pattern, an electrical parameter variation, or a component behavior signature; extract one or more second features from second data, wherein the second data includes one or more of an environmental condition, an operational loading pattern, a maintenance history record, or a component failure; train the machine learning model to determine correlations between the one or more element attributes and one or more health assessment values based on the one or more first features and the one or more second features; and validate the trained machine learning model using validation data to ensure accurate health predictions for operational inverter systems.

Example 32. The non-transitory computer readable medium of example 31, wherein the operations further include any of examples 19 to 20.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method comprising:
receiving, by one or more processors, a data set associated with an inverter of a battery energy storage system;
determining one or more threshold values based on one or more of a thermal health index or a humidity health index associated with the inverter;
applying, by the one or more processors, a machine learning model to the data set to generate a determination that the data set meets the one or more threshold values associated with a health assessment of the inverter, wherein the machine learning model includes an inverter encoder layer configured to perform multi-head attention, pattern recognition, and cross-algorithm learning for processing the data set in real-time; and
controlling, by the one or more processors, one or more operations of the inverter based on the determination that the data set meets the one or more threshold values associated with the health assessment of the inverter.

2. The method of claim 1, wherein the machine learning model is trained by:
receiving first data regarding one or more element attributes, wherein the first data is associated with the inverter;
extracting one or more first features from the first data;
extracting one or more second features from second data; and
training the machine learning model to determine a correlation between the one or more element attributes and the health assessment, based on the one or more first features, and the one or more second features.

3. The method of claim 2, wherein the one or more first features includes one or more of a DC overcurrent, an open phase fault, a gate driver fault, a short circuit fault, a DC bus capacitor health value, a filter condition, or one or more ground faults.

4. The method of claim 2, wherein extracting the one or more first features includes:
determining, by the one or more processors, a thermal response rate for the first data associated with the inverter;
determining, by the one or more processors, one or more cross sensor correlations based on the thermal response rate for the first data associated with the inverter;
determining, by the one or more processors, one or more temperature differentials based on the one or more cross sensor correlations associated with the inverter;
determining, by the one or more processors, a trend analysis for each of a plurality of sensors of the inverter based on the one or more temperature differentials associated with the inverter; and
generating, by the one or more processors, the thermal health index based on one or more of the thermal response rate, the one or more cross sensor correlations, the one or more temperature differentials, or the trend analysis.

5. The method of claim 4, wherein determining the thermal response rate includes analyzing a multi-scale thermal response rate including delta temperature changes between case temperature and assembly temperature relative to switching frequency and DC current changes.

6. The method of claim 4, wherein determining the one or more cross sensor correlations includes analyzing horizontal sensor-to-sensor correlations and vertical stack-to-stack correlations.

7. The method of claim 4, wherein determining the one or more temperature differentials includes analyzing absolute temperature differentials between case to assembly, assembly to electronics and heat exchanger, and electronics to cabin and heat exchanger.

8. The method of claim 2, wherein extracting the one or more first features includes:
determining, by the one or more processors, a temperature spread factor for the first data associated with the inverter;
determining, by the one or more processors, a convergence quality score based on the temperature spread factor associated with the inverter;
determining, by the one or more processors, one or more component response values based on the convergence quality score associated with the inverter;
determining, by the one or more processors, a load impact for the inverter based on the one or more component response values associated with the inverter; and
generating, by the one or more processors, the humidity health index based on one or more of the temperature spread factor, the convergence quality score, the one or more component response values, and the load impact associated with the inverter.

9. The method of claim 8, wherein generating the humidity health index does not include measuring one or more of a humidity value or one or more ambient conditions associated with one or more components of the inverter.

10. The method of claim 8, wherein determining the temperature spread factor includes analyzing an initial spread magnitude among case temperature, PCB temperature, and cabin temperature, and a rate of spread reduction.

11. The method of claim 8, wherein determining the convergence quality score includes analyzing uniformity of convergence, consistency of rates, and pattern stability.

12. The method of claim 1, further comprising:
generating, by the one or more processors, a notification based on the determination that the data set meets the one or more threshold values; and
outputting, by the one or more processors, the notification.

13. The method of claim 1, wherein the one or more operations of the inverter include one or more of outputting a notification, scheduling a maintenance request, preventing one or more actions associated with the inverter, or optimizing the one or more operations of the inverter.

14. The method of claim 1, wherein determining the one or more threshold values further includes determining the one or more threshold values based on one or more component-specific health scores.

15. A method for thermal health monitoring of an inverter in a battery energy storage system, the method comprising:
determining, by one or more processors, a thermal response rate for operational data associated with the inverter using a multi-scale thermal response rate analysis;
determining, by the one or more processors, one or more cross sensor correlations based on the thermal response rate using horizontal sensor-to-sensor analysis and vertical stack-to-stack analysis;
determining, by the one or more processors, one or more temperature differentials based on the one or more cross sensor correlations;
determining, by the one or more processors, a trend analysis for each of a plurality of sensors of the inverter based on the one or more temperature differentials; and
generating, by the one or more processors, a thermal health index based on one or more of the thermal response rate, the one or more cross sensor correlations, the one or more temperature differentials, or the trend analysis associated with the inverter.

16. The method of claim 15, wherein the multi-scale thermal response rate analysis includes determining a delta temperature change between a case temperature and an assembly temperature relative to a switching frequency and a DC current change based on the operational data.

17. The method of claim 15, wherein determining the one or more temperature differentials includes determining one or more absolute temperature differentials between a case and an assembly, the assembly to a plurality of electronics and a heat exchanger, and the plurality of electronics to a cabin and the heat exchanger.

18. A method for training a machine learning model to predict a health of an inverter in a battery energy storage system, the method comprising:
receiving, by one or more processors, first data regarding one or more element attributes associated with the inverter, wherein the first data includes a plurality of operational parameters;
extracting, by the one or more processors, one or more first features from the first data based on analyzing processing algorithms identifying at least one of a thermal response pattern, an electrical parameter variation, or a component behavior signature;
extracting, by the one or more processors, one or more second features from second data, wherein the second data includes one or more of an environmental condition, an operational loading pattern, a maintenance history record, or a component failure;
training, by the one or more processors, the machine learning model to determine correlations between the one or more element attributes and one or more health assessment values based on the one or more first features and the one or more second features; and
validating, by the one or more processors, the trained machine learning model using validation data to ensure accurate health predictions for operational inverter systems.

19. The method of claim 18, wherein the plurality of operational parameters include one or more of a plurality of DC bus voltage measurements, a plurality of multi-stack current readings, a plurality of three-phase AC measurements, a plurality of temperature monitoring data, or a plurality of component status indicators.

20. The method of claim 18, wherein the one or more health assessment values include one or more of a thermal health index, a humidity health index, or one or more component-specific health scores.
